(19) United States
(12) Patent Application Publication
(10) Pub. No.: US 2014/0264531 A1
(43) Pub. Date: Sep. 18, 2014

(54) NONVOLATILE SEMICONDUCTOR MEMORY

(71) Applicant: KABUSHIKI KAISHA TOSHIBA, Tokyo (JP)

(72) Inventors: Akimichi Goyo, Yokohama-shi (JP); Mitsuhiro Noguchi, Yokohama-shi (JP); Hiroyuki Kutsukake, Yokohama-shi (JP)

(73) Assignee: Kabushiki Kaisha Toshiba, Tokyo (JP)

(21) Appl. No.: 13/834,667

(22) Filed: Mar. 15, 2013

(51) Int. Cl. H01L 29/788

(52) U.S. Cl. CPC H01L 29/788
USPC 257/316

(57) ABSTRACT

According to one embodiment, memory includes a memory cell transistor including a floating gate electrode, a control gate electrode and a first inter-gate insulating film between floating gate and control gate electrodes, a field effect transistor including a lower electrode layer, an upper electrode layer, and a second inter-gate insulating film between the lower and upper electrode layers. The lower electrode layer having an n-type silicon film, the second inter-gate insulating film having a first opening, and the upper electrode layer having a p-type silicon film. The p-type silicon film is provided on the n-type silicon film via the first opening.

### CROSS-REFERENCE TO RELATED APPLICATIONS

This application is based upon and claims the benefit of priority from Japanese Patent Application No. 2012-156504, filed Jul. 12, 2012, the entire contents of which are incorporated herein by reference.

### FIELD

Embodiments described herein relate generally to a nonvolatile semiconductor memory.

### BACKGROUND

Nonvolatile semiconductor memories, for example, flash memories are mounted on various electronic devices.

For example, faster input/output of data, improvements in reliability of operation, and reductions in manufacturing costs are demanded from flash memories.

### BRIEF DESCRIPTION OF THE DRAWINGS

FIG. 1 is a schematic diagram illustrating a nonvolatile semiconductor memory according to an embodiment;

FIG. 2 is a schematic diagram illustrating the nonvolatile semiconductor memory according to an embodiment;

FIG. 3 is a schematic diagram illustrating the nonvolatile semiconductor memory according to an embodiment;

FIGS. 4A and 4B are schematic sectional views showing the structure of a nonvolatile semiconductor memory according to a first embodiment;

FIGS. 5A, 5B, 5C and 5D are sectional process charts of a manufacturing method of the nonvolatile semiconductor memory according to the first embodiment;

FIGS. 6A, 6B and 6C are sectional process charts of the manufacturing method of the nonvolatile semiconductor memory according to the first embodiment;

FIGS. 7A, 7B and 7C are sectional process charts of the manufacturing method of the nonvolatile semiconductor memory according to the first embodiment;

FIGS. 8A and 8B are schematic sectional views showing the structure of a nonvolatile semiconductor memory according to a second embodiment;

FIGS. 9A, 9B and 9C are sectional process charts of a manufacturing method of the nonvolatile semiconductor memory according to the second embodiment;

FIGS. 10A, 10B and 10C are sectional process charts of the manufacturing method of the nonvolatile semiconductor memory according to the second embodiment;

FIGS. 11A and 11B are sectional process charts of the manufacturing method of the nonvolatile semiconductor memory according to the second embodiment;

FIGS. 12A and 12B are schematic sectional views showing the structure of a nonvolatile semiconductor memory according to a third embodiment;

FIGS. 13A, 13B and 13C are sectional process charts of a manufacturing method of the nonvolatile semiconductor memory according to the third embodiment;

FIGS. 14A, 14B and 14C are sectional process charts of the manufacturing method of the nonvolatile semiconductor memory according to the third embodiment;

FIGS. 15A and 15B are sectional process charts of the manufacturing method of the nonvolatile semiconductor memory according to the third embodiment;

FIGS. 16A and 16B are schematic sectional views showing the structure of a nonvolatile semiconductor memory according to a fourth embodiment;

FIGS. 17A, 17B, 17C and 17D are sectional process charts of a manufacturing method of the nonvolatile semiconductor memory according to the fourth embodiment;

FIGS. 18A, 18B and 18C are sectional process charts of the manufacturing method of the nonvolatile semiconductor memory according to the fourth embodiment;

FIGS. 19A and 19B are schematic sectional views showing the structure of a nonvolatile semiconductor memory according to a fifth embodiment;

FIGS. 20A, 20B and 20C are sectional process charts of a manufacturing method of the nonvolatile semiconductor memory according to the fifth embodiment;

FIGS. 21A and 21B are schematic sectional views showing the structure of a nonvolatile semiconductor memory according to a sixth embodiment;

FIGS. 22A, 22B and 22C are sectional process charts of a manufacturing method of the nonvolatile semiconductor memory according to the sixth embodiment; and

FIGS. 23A, 23B and 23C are diagrams illustrating a modification of the nonvolatile semiconductor memory according to an embodiment.

### DETAILED DESCRIPTION

The embodiments will be described below in detail with reference to the drawings. In the description that follows, the same reference numerals are attached to elements having the same function and configuration and a duplicate description will be provided when necessary.

In general, according to one embodiment, a nonvolatile semiconductor memory includes a memory cell transistor to which data can electrically be written and from which data can electrically be erased, the memory cell transistor including a floating gate electrode having a first p-type silicon film, a control gate electrode having a second p-type silicon film, and a first inter-gate insulating film between the first and second p-type silicon films; a first select gate transistor connected to one end of the memory cell transistor; and first field effect transistor including a gate insulating film and a gate electrode, the gate electrode having a lower electrode layer above the gate insulating film, an upper electrode layer above the lower electrode layer, and a second inter-gate insulating film between the lower electrode layer and the upper electrode layer, the lower electrode layer having a first n-type silicon film, the second inter-gate insulating film having a first opening, and the upper electrode layer having a third p-type silicon film, wherein the third p-type silicon film is provided on the first n-type silicon film via the first opening.

### EMBODIMENT

### (0) Overall Configuration of a Nonvolatile Semiconductor Memory

The configuration of a nonvolatile semiconductor memory described in an embodiment will be described with reference to FIGS. 1 to 3.

FIG. 1 is a diagram exemplifying a chip layout of a nonvolatile semiconductor memory according to an embodiment.

As shown in FIG. 1, memory cell arrays 100A, 100B including memory cells are provided in a chip (on a semiconductor substrate).

The memory cell arrays 100A, 100B include a plurality of cell blocks Block 0, Block 1, . . . , Block m as a control unit of the nonvolatile semiconductor memory, respectively. Data is written to, data is erased from, or data is read from memory cells capable of storing data.

To control writing to or erasure/reading from memory cells, a peripheral circuit is arranged around the memory cell array.

The peripheral circuit includes a power supply capacitor, logical circuit and control circuit 209 that controls an external signal, row decoders 201A, 201B that raise the potential of word lines, and sense amplifiers 202A, 202B that detect the current/potential of bit lines. Each peripheral circuit is formed of an N-type or P-type field effect transistor.

The nonvolatile semiconductor memory of an embodiment described below is, for example, a flash memory (flash EEPROM).

FIG. 2 is an equivalent circuit diagram showing a memory cell array of the flash memory according to an embodiment. FIG. 3 is a sectional view schematically showing the structure of the memory cell array of the flash memory according to an embodiment.

In FIGS. 2 and 3, a NAND flash memory is shown as an example.

As shown in FIGS. 2 and 3, a plurality of memory cell transistors MT0, MT1, MT2, . . . , MTn−1 is connected in series in a column direction in such a way that the adjacent memory cell transistors share a source 27 or a drain 27 and select gate transistors ST0, ST1 are arranged at one end and the other of the plurality of memory cell transistors MT0, MT1, MT2, . . . , MTm−1 connected in series.

The configuration formed from memory cell transistors MT0, MT1, MT2, . . . , MTn−1 connected in series and select gate transistors ST0, ST1 arranged at both ends thereof will be called a NAND cell unit below. Also, a series connection of current paths of a plurality of memory cell transistors is called a NAND connection.

For the clarification of description, the memory cell transistors MT0, MT1, MT2, . . . , MTn−1 are denoted as a memory cell transistor MT if not distinguished and the select gate transistors ST0, ST1 are denoted as a select gate transistor ST if not distinguished.

In the NAND flash memory, as shown in FIG. 3, the memory cell transistor MT has a stack gate structure formed by a charge storage layer (for example, a floating gate electrode) 4 and a control gate electrode 9 being stacked via a gate insulating film 2 on a semiconductor substrate 1.

A memory cell array is configured by a plurality of NAND cell units NU0, NU1, . . . , NUk−1 being arranged in a matrix form. The NAND cell units NU0, NU1, . . . , NUk−1 are denoted as a NAND cell unit NU if not distinguished.

The unit formed by a plurality of NAND cell units NU arranged in a row direction is called a NAND cell block.

The gates of the select gate transistors ST0 arranged in the same row (row direction) are connected to the same select gate line SGD. The gates of the select gate transistors ST1 arranged in the same row (row direction) are connected to the same select gate line SGS.

The control gates of the memory cell transistors MT arranged in the same row (row direction) are connected to the same control gate line WL0, WL1, WL2, . . . , WLn−1. The control gate lines WL0, WL1, WL2, . . . , WLn−1 function as word lines WL0, WL1, WL2, . . . , WLn−1 of the flash memory.

Each of the NAND cell units NU is connected to one of a plurality of bit lines BL0, BL1, BL2, . . . , BLk−1.

If n memory cell transistors MT are connected in series in the NAND cell unit NU, the number of word lines included in one NAND cell block is n.

If the number of NAND cell units NU included in one NAND cell block is k, the number of bit lines included in one NAND cell block is k.

For the clarification of description below, the word lines (control gate lines) WL0, WL1, WL2, . . . , WLm−1 are denoted as a word line WL if not distinguished and the bit lines BL0, BL1, BL2, . . . , BLk−1 are denoted as a bit line BL if not distinguished.

In two NAND cell units NU arranged in the column direction on the source side of the NAND cell units NU, as shown in FIG. 3, a source diffusion layer 27b of the two select gate transistors ST1 on the source side is connected to a source line SL via a common contact plug CPb.

In two NAND cell units NU arranged in the column direction on the drain side of the NAND cell units NU, a drain diffusion layer 27a of the two select gate transistors ST0 on the drain side is connected to the bit line BL via common contact plugs CPa, CV and an intermediate interconnect MO.

The memory cell transistor MT stores data in a nonvolatile manner by a charge storage state of the floating gate electrode 4 as a charge storage layer.

For example, binary (1 bit) data is stored by the memory cell transistor MT by setting a state having a high threshold voltage after electrons being injected into the floating gate electrode from a channel via a tunnel insulating film as “0” data and a state having a low threshold voltage after electrons in the floating gate electrode being discharged into the channel as “1” data.

By subdividing the control of the threshold distribution, a multi-level storage method by which one memory cell transistor MT stores 4-level (2 bits) or 8-level (3 bits) data can be used.

### (1) First Embodiment

A nonvolatile semiconductor memory (for example, a NAND flash memory) according to the first embodiment and a manufacturing method thereof will be described with reference to FIGS. 4A to 7C.

### <Structure>

The structure of a NAND flash memory according to the present embodiment will be described by using FIGS. 4A and 4B.

FIGS. 4A and 4B show cross section structures of a memory cell transistor, select gate transistor, and peripheral transistor included in the NAND flash memory according to the present embodiment. In FIGS. 4A and 4B, a portion of the NAND cell unit is extracted and shown. In FIGS. 4A and 4B, main component members of each transistor are shown and an illustration of the contact plugs and inter-layer insulating film are omitted to clarify the description.

FIG. 4A shows a cross section structure of the memory cell transistor MT and the select gate transistor ST in a NAND flash memory according to the present embodiment along a gate length direction (also called a bit line direction) of the transistors.

In FIG. 4A, a structure in which three memory cell transistors MT are connected in series is shown.

In a formation region of the memory cell transistor MT of a memory cell array region 20, for example, the gate insulating film (tunnel insulating film) 2 of the memory cell transistor MT is provided on the semiconductor region (active region) 1 (AA) made of p-type silicon whose impurity concentration of boron (B) is between 10¹⁴ cm⁻³ and 10¹⁹ cm⁻³.

The gate insulating film 2 is formed by using a silicon oxide film (SiO₂), oxynitride film, silicon nitride film, or a laminated film of two or more of these films formed so as to have a thickness ranging, for example, from 1 nm to 10 nm.

The floating gate electrode (charge storage layer) 4 made of a p-type semiconductor is provided on the gate insulating film 2. The floating gate electrode 4 is made of p-type polysilicon to which boron is added in the concentration ranging from 10¹⁸ cm⁻³ to 10²² cm⁻³. The floating gate electrode 4 has a thickness ranging from 30 nm to 120 nm.

An interpoly dielectric film (inter-gate insulating film) 5 is provided on the floating gate electrode 4.

The interpoly dielectric film 5 is made of one of, for example, silicon oxide film/silicon nitride film/silicon oxide film, silicon nitride film/silicon oxide film/silicon nitride film/silicon oxide film/silicon nitride film, silicon oxide film/AlOx film/silicon oxide film, silicon oxide film/HfAlOx film/silicon oxide film, silicon oxide film/HfOx film/silicon oxide film, and silicon oxide film formed so that the total thickness becomes between 2 nm and 30 nm.

A control gate electrode CG is provided on the interpoly dielectric film 5.

The control gate electrode CG includes a p-type (p⁺-type) first polysilicon film 6 to which boron is added in the concentration ranging, for example, from 10¹⁸ cm⁻³ to 10²² cm⁻³, a p-type (p⁺-type) second polysilicon film 82 to which boron is added in the concentration ranging, for example, from 10¹⁸ cm⁻³ to 10²² cm⁻³ on the film 6, for example, a WN (tungsten nitride) film 9 on the polysilicon film 82, and a W (tungsten) film 10 stacked on the WN film 9. The first polysilicon film 6 has a thickness ranging, for example, from 5 nm to 100 nm. The second polysilicon film 82 has a thickness ranging, for example, from 5 nm to 100 nm. The WN film 9 has a thickness ranging, for example, from 2 nm to 40 nm. The W film 10 has a thickness ranging, for example, from 10 nm to 100 nm.

The WN film 9 and the W film 10 become backing interconnects of the control gate electrode CG used as the word lines WL. The WN film 9 functions, for example, as a barrier metal.

An interface resistance between the first polysilicon film 6 and the WN film 9 may be lowered by additionally forming a WSi (tungsten silicide) film 9Z having a thickness ranging, for example, from 0.5 nm to nm between the first polysilicon film 6 and the WN film 9. For example, the undersurface of the WSi film 9Z is in contact with the top surface of the first polysilicon film 6 and the top surface of the WSi film 9Z is in contact with the WN film 9.

A cap material 11 formed from SiN (silicon nitride) having a thickness ranging from 1 nm to 100 nm is stacked on the control gate electrode CG.

In the memory cell transistor MT included in a flash memory according to the present embodiment, the second polysilicon film 82 in the control gate electrode CG is p-type silicon, instead of n-type silicon.

The side face of the control gate electrode CG and the side face of the floating gate electrode 4 are covered with a protective film 13 using SiO₂, SiN, or a laminated film of these formed so as to have a thickness ranging from 1 nm to 10 nm.

The control gate electrode CG may have a structure formed of a laminated film of polysilicon and WSi (tungsten silicide), CoSi (cobalt silicide), NiSi (nickel silicide), or a tungsten. If the control gate electrode CG has a structure other than tungsten (for example, silicide), the cap material 11 may not be provided on the control gate electrode CG.

N-type diffusion layers (hereinafter, also called a source/drain diffusion layer) 27 to be a source electrode or drain electrode of the memory cell transistor MT are formed in the semiconductor substrate 1 at both ends in the channel length direction of the gate electrode 4 of these memory cell transistors MT. These n-type diffusion layers 27 as source/drain electrodes are formed in the depth of 10 nm to 500 nm so that the surface concentration of phosphorus (P), arsenic (As) or antimony (Sb) becomes, for example, between 10¹⁷ cm⁻³ and 10²¹ cm⁻³. Incidentally, the n-type diffusion layer 27 can be changed to a p-type diffusion layer.

A memory cell of a floating gate type nonvolatile EEPROM (for example, a flash memory) is formed from the memory cell transistor MT including the floating gate electrode 4, the control gate electrode CG, and the n-type diffusion layer 27 as a source/drain. NAND connection of the memory cell transistors MT is realized by the n-type diffusion layer 27 of the memory cell transistor MT being shared by the adjacent memory cell transistors MT.

The gate length of the floating gate electrode 4 is set to, for example, 0.5 μm or less and 0.01 μm or more. The interval between the control gate electrodes CG of the memory cell transistors MT is set to, for example, 5 nm or more and 40 nm or less. It is assumed, for example, that the interval between the control gate electrodes CG of the memory cell transistors MT is set smaller than the height (thickness) of the control gate electrodes CG.

In NAND-connected memory cell transistors MT, the select gate transistors ST0, ST1 are provided at one end and the other end thereof to select the memory cell block.

A gate electrode 4, SG of the select gate transistor ST is provided on the gate insulating film 2 in the p-type silicon region 1 (AA). The gate electrode 4, SG of the select gate transistor ST includes a lower electrode layer 4 made of p-type polysilicon on the gate insulating film 2, the interpoly dielectric film 5 on the lower electrode layer 4, and a select gate layer (upper electrode layer) SG on the lower electrode layer 4 and the interpoly dielectric film 5.

The gate insulating film 2 of the select gate transistor ST is formed substantially simultaneously with the gate insulating film 2 of the memory cell transistor MT and is formed by using the same material.

The lower electrode layer (also called a lower select gate electrode layer) 4 of the select gate transistor ST is formed substantially simultaneously with the floating gate electrode 4 of the memory cell transistor MT and is formed by using substantially the same material. The lower electrode layer 4 of the select gate transistor ST is made of, like the floating gate electrode 4, p-type polysilicon to which boron in the concentration ranging, for example, from 10¹⁸ cm⁻³ to 10²² cm⁻³ is added. The lower electrode layer 4 has a thickness ranging from 30 nm to 120 nm.

A select gate layer (also called an upper electrode layer or upper select gate electrode layer) SG of the select gate transistor ST includes substantially the same members 6, 82, 9, 10 as those of the control gate electrode CG of a memory cell transistor MT.

In the present embodiment, the select gate layer SG of the select gate transistor ST is formed of the p-type first polysilicon film 6 to which boron in the concentration ranging from 10¹⁸ cm⁻³ to 10²² cm⁻³ is added, the p-type second polysilicon film 82 to which boron in the concentration ranging from 10¹⁸ cm⁻³ to 10²² cm⁻³ is added, the WN (tungsten nitride) film 9, and the W (tungsten) film 10.

The select gate layer SG is in contact with the lower electrode layer 4 via an opening formed in the interpoly dielectric film 5.

The n-type diffusion layer 27 to be a source electrode or drain electrode shared with the memory transistors MT is formed in the silicon region 1 on the memory cell side of the gate electrode 4, SG of a select gate transistor ST. An n-type diffusion layer 27z to be a source electrode or drain electrode is formed in the silicon region 1 on the opposite side of the memory cell side of the gate electrode 4, SG of the select gate transistor ST.

The side face on the memory cell side of the gate electrode 4, SG of the select gate transistor ST is covered with the protective film 13, which is the same as the film on the side face of the control gate electrode CG, and the side face on the opposite side of the memory cell side of the gate electrode 4, SG of the select gate transistor ST is not covered with the protective film 13 and instead is covered with a insulating film (for example, a sidewall insulating film) that is different from (discontinuous to) the protective film 13.

The interval between the gate electrode 4, SG of the select gate transistor ST and the control gate electrode CG of the memory cell transistor MT is set to, for example, 5 nm or more and 40 nm or less.

FIG. 4B shows a cross section structure of a peripheral transistor along the gate length direction of the transistor and included in a flash memory in the present embodiment.

In FIG. 4B, a peripheral transistor taking, for example, a field effect transistor in an N-channel MOS structure (hereinafter, denoted as a MOS transistor) as an example is shown. Incidentally, a P-channel MOS transistor has the same structure as an N-channel MOS transistor except that the conductivity type of the diffusion layer is different. An N-channel MOS transistor can be arranged in a p-type well region or on a p-type semiconductor substrate and a P-channel MOS transistor can be arranged in an n-type well region. When an n-type semiconductor substrate is used, a P-channel MOS transistor can be arranged on the n-type semiconductor substrate.

A peripheral transistor Tr is provided on the same semiconductor substrate as the memory cell transistor MT and the select gate transistor ST.

The peripheral transistor Tr is formed substantially simultaneously with the memory cell transistor MT and includes substantially the same material.

In a formation region (called a peripheral region) 21 of a MOS transistor as a peripheral transistor, the p-type silicon region (semiconductor region) 1 is doped with, for example, a p-type impurity such as boron and the concentration of the p-type impurity in the depth up to about 1 μm from the surface of the silicon region 1 is 10¹⁶ cm⁻³ or more and 5×10¹⁸ cm⁻³ or less. A p-type well or an n-type well can be formed in the p-type silicon region 1.

A gate electrode 3, GC of the peripheral transistor Tr is provided in the p-type semiconductor region 1 via the gate insulating film 2.

The gate insulating film 2 is formed by using a silicon oxide film (SiO₂), oxynitride film, silicon nitride film, or a laminated film of two or more of these films formed so as to have a thickness ranging, for example, from 1 nm to 10 nm.

By adjusting the thickness (and the material) of the gate insulating film 2 of the peripheral transistor Tr to the thickness (and the material) of the gate insulating film 2 of the memory cell transistor MT, the gate insulating films 2 of the memory cell transistor MT and the peripheral transistor Tr can be formed simultaneously, reducing the number of manufacturing processes of the flash memory.

The gate electrode 3, GC of the peripheral transistor Tr includes a lower electrode layer 3 made of an n-type semiconductor layer on the gate insulating film 2, the interpoly dielectric film 5 on the lower electrode layer 3, and a gate contact layer GC provided on the interpoly dielectric film 5.

The lower electrode layer 3 of an n-type semiconductor layer is made of, for example, n-type (n⁺-type) polysilicon to which phosphorus, arsenic, or antimony is added in the concentration ranging from 10¹⁸ cm⁻³ to 10²² cm⁻³.

The gate contact layer GC is provided, for example, on the interpoly dielectric film 5 and is formed from the first p-type polysilicon film 6 to which boron is added in the concentration ranging, for example, from 10¹⁸ cm⁻³ to 10²² cm⁻³, the second p-type polysilicon film 82 provided on the lower electrode layer 3 and the polysilicon film 6, the WN film 9 provided on the polysilicon film 82, and the W film 10 stacked on the WN film 9. The first p-type polysilicon film 6 of the gate contact layer GC has a thickness ranging from 5 nm to 100 nm. The WN film 9 has a thickness ranging from 2 nm to 40 nm and the W film 10 has a thickness ranging from 10 nm to 100 nm.

In the present embodiment, the MOS transistor Tr has, instead of n-type polysilicon, the second p-type (p⁺-type) polysilicon film 82 having a thickness ranging, for example, from 5 nm to 100 nm and to which boron in the concentration ranging from 10¹⁸ cm⁻³ to 10²² cm⁻³ is added provided on the lower electrode layer 3 made of n-type polysilicon and the p-type first polysilicon film 6.

A structure (laminated film) stacked on the lower electrode layer (n-type polysilicon layer) 3 on the gate insulating film 2 and including a member substantially the same as the control gate electrode CG of the memory cell transistor MT or at least one of a plurality of members to form the control gate electrode CG of the memory cell transistor MT in a peripheral transistor Tr will be called a gate contact layer (GC electrode) below.

An n-type diffusion layer 16 functioning as an LDD region of the source and drain of a MOS transistor Tr is provided in a surface region of the p-type semiconductor region 1 as the formation region 21 of the MOS transistor Tr. The n-type diffusion layer 16 includes at least one of, for example, phosphorus, arsenic, and antimony so that the impurity concentration on the surface of the diffusion layer 16 becomes 10¹⁷ cm⁻³ to 10²⁰ cm⁻³. The junction depth of the n-type diffusion layer 16 is, for example, 10 nm to 300 nm. The n-type diffusion layer 16 is formed self-aligningly with respect to the sidewall insulating film (not shown) on the side face of the gate electrode 3, GC of the MOS transistor Tr.

For example, the cap material 11 formed of SiN (silicon nitride) in the thickness ranging, for example, from 1 nm to 100 nm is provided in an upper portion of the gate contact layer GC of the MOS transistor.

A sidewall insulating film (not shown) made of SiO₂, SiN, or a laminated film of these in the thickness ranging, for example, from 10 nm to 100 nm is formed on the side face of the gate electrode 3, GC of the peripheral transistor Tr.

Thus, in the present embodiment, the gate contact layer GC of the peripheral transistor includes the first p-type polysilicon film 6, the second p-type polysilicon film 82, the WN film 9, and the W film 10.

A mask material 12 formed from SiO₂ or SiN (silicon nitride) in the thickness ranging, for example, from 2 nm to 100 nm is provided on the cap material 11 on the gate electrode CG, SG, GC of each transistor MT, ST, Tr.

A first gap formation insulating film (first inter-layer insulating film) 14 formed from SiO₂ or SiN (silicon nitride) having the thickness ranging, for example, from 2 nm to 100 nm is formed. Also, an insulating film (second gap formation insulating film/inter-layer insulating film) 15 is formed on the gap formation insulating film 14.

An air gap (clearance, void) AG is provided between the adjacent memory cell transistors MT and between the memory cell transistor MT and the select gate transistor ST due to the gap formation insulating film 14.

While only the N-type MOS transistor is illustrated as a peripheral transistor in the present embodiment, a P-channel field effect transistor as a peripheral transistor Tr (hereinafter, called a P-type MOS transistor) is provided on the same semiconductor substrate as a memory cell transistor MT and N-type MOS transistor Tr.

The P-type MOS transistor as a peripheral transistor has substantially the same structure as the above MOS transistor. The P-type MOS transistor as a peripheral transistor has a different conductivity type of the diffusion layer 16 as a source/drain from that of an N-type MOS transistor and has substantially the same structure of gate electrode as that of an N-type MOS transistor.

Component members of the gate contact layer GC of the peripheral transistor Tr are formed substantially simultaneously with those of the control gate electrode CG of the memory cell transistor MT.

However, an opening is formed in the interpoly dielectric film 5 of the peripheral transistor Tr and the gate contact layer GC and the lower electrode layer 3 are connected through the opening.

That is, a portion of the interpoly dielectric film 5 is removed by etching in the peripheral transistor Tr and the lower electrode layer 3 and the gate contact layer GC are in contact.

Also in the select gate transistor ST, like the peripheral transistor Tr, the lower electrode layer 4 and the select gate layer SG are in contact via an opening in the interpoly dielectric film 5.

Accordingly, the operation of a MOS transistor is realized in the peripheral transistor Tr and the select gate transistor ST.

The opening formed in the interpoly dielectric film 5 in the peripheral transistor Tr and the select gate transistor ST and portions brought into contact with each other via the opening will be called an EI portion.

A p-type polysilicon layer may be used as a floating gate electrode to improve data retention of a memory cell transistor. P-type polysilicon is correspondingly used for the control gate electrode in the memory cell transistor.

To form a good contact between the lower electrode layer and gate contact layer in a peripheral transistor via the EI portion, a lower electrode made of n-type polysilicon and an n-type polysilicon film provided in a gate contact layer may be used.

When gates are formed by using polysilicon of different conductivity types for a memory cell transistor and peripheral transistor, a manufacturing process that fabricates a p-type gate electrode for the memory cell transistor and an n-type gate electrode for the peripheral transistor, respectively, is adopted.

In the formation process of a peripheral transistor, for example, ions are implanted twice separately from the formation process of a memory cell transistor.

In a flash memory according to the first embodiment, the control gate electrode CG of the memory cell transistor MT and the gate contact layer GC of the gate electrode 3, GC of the peripheral transistor Tr are formed by using a substantially common manufacturing process and include substantially the same materials.

In the gate electrode 3, GC of the peripheral transistor Tr according to the present embodiment, the gate contact layer GC includes the p-type polysilicon film 82 formed substantially simultaneously with the p-type polysilicon film 82 used for the control gate electrode CG of the memory cell transistor MT and having the same material.

Thus, with the adoption of a p-type gate (formed by using a p-type semiconductor) for the gate contact layer GC of the gate electrode 3, GC of a peripheral transistor Tr, like the control gate electrode CG of a memory cell transistor MT, an increase in manufacturing costs of flash memories can be reduced by adopting common manufacturing processes of flash memories for flash memories in the present embodiment.

The gate electrode 3, GC of a MOS transistor in the present embodiment has a structure in which the n-type polysilicon film 3 of the lower electrode layer 3 and the p-type second polysilicon film 82 of the gate contact layer GC are in contact in the EI portion inside the gate electrode 3, GC. An impurity of 10¹⁸ cm⁻³ or more is added to each of the n-type polysilicon film 3 and the p-type second polysilicon film 82.

Thus, when the peripheral transistor Tr is driven (when a gate voltage is applied), a pn junction formed between the p-type second polysilicon film 82 and the n-type polysilicon film 3 in the gate electrode 3, GC of the peripheral transistor Tr is in a forward bias applying state. That is, because no depletion layer is formed between the second polysilicon layer 82 and the lower electrode layer 3, the voltage applied to the gate electrode 3, GC in contact with the gate insulating film 2 increases. As a result of the tunnel effect of the pn junction of the p-type and n-type polysilicon films 82, 3 based on the forward bias state, an EI resistance between the lower electrode layer 3 and the gate contact layer GC can be reduced.

Also in a flash memory according to the present embodiment, both of the first polysilicon film 6 and the second polysilicon film 82 forming the gate contact layer GC of the peripheral transistor Tr have the p-type conductivity type. Thus, in contrast to a case when an n-type polysilicon film is provided on a p-type polysilicon film in the gate electrode of a peripheral transistor Tr, a p-type gate structure can be formed without causing depletion between the two polysilicon films 6, 82 forming the gate contact layer GC of a peripheral transistor Tr.

Therefore, manufacturing costs of a nonvolatile semiconductor memory according to the first embodiment can be reduced. Also, electrical characteristics of a nonvolatile semiconductor memory according to the first embodiment can be improved.

### <Manufacturing Method>

The manufacturing method of a nonvolatile semiconductor memory (NAND flash memory) according to the first embodiment will be described with reference to FIGS. 5A to 7C. Here, the manufacturing method of a flash memory according to the present embodiment will be described by using FIGS. 3 and 4 when appropriate.

As shown in FIG. 5A, the gate insulating film 2 is formed in the silicon region 1 to be the memory cell array region 20 and the peripheral region 21 of a semiconductor substrate by using, for example, the thermal oxidation method. A non-doped polysilicon layer is deposited on the gate insulating film 2 by, for example, the CVD method.

Prior to the process shown in FIG. 5A, a process of forming an n-type well and a p-type well in the semiconductor substrate can be executed by using ion implantation or the like.

A resist film 90 is formed on the polysilicon layer 4. The resist film 90 is patterned by lithography and etching and the resist film in the memory cell array region 20 is removed. Accordingly, the top surface of the polysilicon layer 4 in the memory cell array region 20 is exposed and the top surface of a polysilicon layer 3Z in the peripheral region 21 is covered with the resist film 90.

Using the patterned resist film 90 as a mask, p-type impurity ions of, for example, boron are injected in the concentration ranging from 10¹⁴ cm⁻² to 10¹⁶ cm⁻² into the polysilicon layer 4 to be a floating gate electrode of a memory cell transistor and a lower electrode layer of a select gate transistor by using ion implantation or the like in the memory cell array region 20.

Accordingly, the polysilicon layer 4 to form a floating gate electrode is changed to the type.

After a p-type impurity being added to the polysilicon layer 4 in the memory cell array region 20, the resist film 90 in the peripheral region 21 is removed.

As shown in FIG. 5B, a patterned resist film 91 is formed on the polysilicon layer 4 by a method similar to the above method. The resist film 91 is patterned so that the top surface of the polysilicon layer 4 in the memory cell array region 20 is covered by the resist film 91 and the polysilicon layer 3 in the peripheral region 21 is exposed.

In the peripheral region 21, n-type impurity ions of, for example, P or As are injected in the concentration ranging from 10¹⁴ cm⁻² to 10¹⁶ cm⁻² into the polysilicon layer 3 to be a lower electrode layer of a MOS transistor as the peripheral transistor by using ion implantation or the like. Accordingly, the polysilicon layer 3 to form a lower electrode layer of the gate electrode of the MOS transistor is changed to the n⁺ type.

When an n-type silicon layer and a p-type silicon layer are produced differently by ion implantation into the non-doped silicon layer deposited simultaneously in the memory cell array region 20 and the peripheral region 21, the thickness of the p-type silicon layer 4 in the memory cell array region 20 and the thickness of the n-type silicon layer 3 in the peripheral region 21 are substantially the same.

As shown in FIG. 5C, the interpoly dielectric film (inter-gate insulating film) 5 is formed on the n-type and p-type polysilicon layers 3, 4 in the memory cell array region 20 and the peripheral region 21 by using, for example, the CVD method, oxidation treatment, or nitriding treatment. The first polysilicon film 6 to be a portion of the control gate electrode of the memory cell transistor is formed on the interpoly dielectric film 5 by, for example, the CVD method.

A resist film 92 is formed on the first polysilicon film 6 in the memory cell array region 20 and the peripheral region 21. Then, an opening OP is formed in the resist film 92 in the position corresponding to the EI portion of the select gate transistor and the peripheral transistor.

As shown in FIG. 5D, an EI portion is formed inside a first polysilicon film 6A and the interpoly dielectric film 5 by using etching by the RIE method using the resist film with an opening as a mask. After the EI portion being formed, the resist film on the first polysilicon film 6A is removed.

After the EI portion being formed, as shown in FIG. 6A, a second polysilicon film 82Z to be a portion of the control gate electrode of the memory cell transistor is formed so as to have a thickness between 5 nm and 200 nm.

In the memory cell array region 20 and the peripheral region 21, the second polysilicon film 82Z comes into contact with the n-type or p-type silicon layer 3, 4 in the lower layer through the EI portion.

The thickness of the second polysilicon film 82Z is preferably set so that the EI portion formed inside the first polysilicon film 6 and the interpoly dielectric film 5 is backfilled with the second polysilicon film 82Z.

As shown in FIG. 6B, the height of the stacked film to form the gate electrode of each transistor is reduced by the top surface of a second polysilicon film 82Y being etched back. At this point, the sum (thickness of remaining films) of the thickness of the first polysilicon film 6 and the thickness of the second polysilicon film 82Y remaining on the top surface of the interpoly dielectric film 5 is set to the range between 5 nm and 100 nm.

As shown in FIG. 6C, p-type impurity ions of boron, BF₂, or indium are injected into the polysilicon films 6, 82 in the concentration ranging from 10¹³ cm⁻² to 10¹⁷ cm⁻². Accordingly, the polysilicon films 6, 82 are changed to the p⁺ type.

At this point, the conductivity type of the polysilicon film 6, 82 above the interpoly dielectric film 5 is not produced differently in the memory cell array region 20 and the peripheral region 21 and thus, a p⁺-type semiconductor region is formed by performing, for example, overall ion implantation without applying a resist to the polysilicon films 6, 82.

As a method of changing a polysilicon film to the p type, for example, a p-type polysilicon film may be formed by depositing polysilicon while a B₂H₆ gas being added during deposition of the polysilicon film to form a p⁺-type polysilicon film on the entire surface of the memory cell array region 20 and the peripheral region 21. In this case, the ion implantation process can be reduced by injecting an impurity using a doping gas during deposition of polysilicon.

According to the present embodiment, therefore, a manufacturing process of forming a polysilicon film 6, 82 of the same conductivity type is executed without making the conductivity type of the polysilicon film 6, 82 on the interpoly dielectric film 5 (above the floating gate electrode and lower electrode) different in the memory cell array region 20 and the peripheral region 21. Accordingly, the present embodiment can reduce one lithography process compared with a case when p-type and n-type polysilicon films are formed differently in the memory cell array region 20 and the peripheral region 21. Therefore, manufacturing costs of flash memories can be reduced by reducing the manufacturing process of flash memories. Moreover, the influence of contamination of polysilicon by organic matter caused by the lithography process can be reduced by reducing the lithography process to produce differently polysilicon films of different conductivity types.

After the p-type second polysilicon 82 being formed, as shown in FIG. 7A, the WN (tungsten nitride) film 9 and the W (tungsten) film 10 are deposited on the p-type polysilicon film 82 to form, for example, a backing film of the control gate electrode of the memory cell transistor functioning as a word line.

An SiN film is deposited on the W film 10 as the cap material 11 and the mask material 12.

Then, in the memory cell array region 20, as shown in FIG. 7B, a region to be positioned between memory cell transistors is opened in a resist film (not shown) formed on the cap material 11, 12 to etch the mask material 12, the cap material 11, the W film 10, the WN film 9, the second p-type polysilicon film 82, the first p-type polysilicon film 6, the interpoly dielectric film 5, and the floating gate electrode 4 by, for example, the RIE method.

Accordingly, the control gate electrode CG of the memory cell transistor MT and a word line of the flash memory are formed. Also, the independent floating gate electrode 4 is formed for each memory cell transistor MT.

When, for example, the gate of the memory cell transistor MT is processed, formation members of the gate electrode is covered with a resist film in the select gate transistor formation region of the memory cell array region 20 and the peripheral region 21 so that processes of the select gate transistor and peripheral transistor are not performed.

Using the gate electrode 4, CG of the formed memory cell transistor MT as a mask, n-type impurity ions of P or As are injected in the range of 10¹³ cm⁻² to 10¹⁵ cm⁻² into the formation region of a source/drain of the memory cell transistor MT by using, for example, ion implantation. Accordingly, an n-type diffusion layer to be a source/drain electrode of the memory cell transistor MT is formed in the p-type silicon region 1 self-aligningly with respect to the gate electrode 4, CG of the memory cell transistor MT.

The protective film 13 is deposited on the entire surface of the memory cell array region 20 and the peripheral region 21 like covering the side face of the gate electrode 4, CG of the memory cell transistor MT.

Next, as shown in FIG. 7C, the insulating film (gap formation film) 14 and the insulating film (gap formation film/inter-layer insulating film) 15 with poor coverage such as d-TEOS are formed in, for example, the memory cell array region 20 and the peripheral region 21. Accordingly, the air gap AG is formed between word lines (between gate electrodes 4, CG of memory cell transistors MT).

Then, a laminated body to form a gate electrode is processed by lithography and etching in a region on the opposite side of the memory cell side of the select gate transistor formation region in the memory cell array region 20 and in the peripheral region 21 to form the gate electrode 4, SG of the select gate transistor ST and the gate electrode 3, GC of the peripheral transistor Tr.

In the present embodiment, the second polysilicon film 82 and the first polysilicon film 6 are formed of a polysilicon doped with the same impurity in the select gate transistor ST and the peripheral transistor Tr. Thus, there arises almost no difference in etching rate between silicon films resulting from doping (different conductivity types) between the select gate transistor ST and the peripheral transistor Tr so that more uniform etching can be performed when a gate electrode is processed.

A source/drain electrode on the opposite side of the memory cell side of the select gate transistor ST and a source/drain electrode of the peripheral transistor are formed substantially simultaneously in the p-type semiconductor region 1 by n-type impurity ions of P or As being injected by using, for example, ion implantation in the range of 10¹³ cm⁻² to 10¹⁶ cm⁻².

The p-type diffusion layer as a source/drain electrode of the P-type MOS transistor of the peripheral transistor Tr is formed by a process that is different from the process of forming a source/drain electrode of the N-type MOS transistor. A source/drain electrode of the P-type MOS transistor is formed in an n-type well by p-type impurity ions being injected by using ion implantation or the like using the gate electrode formed simultaneously with the N-type MOS transistor as a mask in a process that is different from the injection process of n-type impurity ions.

A sidewall insulating film is formed on exposed surfaces of the select gate transistor ST and the peripheral transistor Tr.

Subsequently, an inter-layer insulating film is formed on the semiconductor region 1 according to known technology. Then, a contact plug and each interconnect are sequentially formed in the inter-layer insulating film and on the inter-layer insulating film.

With the above processes, a NAND flash memory according to the present embodiment is formed.

A flash memory according to the first embodiment formed by the manufacturing process described using FIGS. 5A to 7C has a p⁺-type gate structure in which the floating gate electrode 4 and the control gate electrode CG included in the memory cell transistor MT and the lower electrode layer 4 and the select gate layer SG included in the gate electrode of the select gate transistor ST in the memory cell array region 20 and the gate contact layer GC included in the gate electrode of the peripheral transistor Tr in the peripheral region 21 include a pt-type polysilicon film, except that the lower electrode layer 3 of the peripheral transistor (MOS transistor) Tr made of a silicon layer deposited simultaneously with the floating gate electrode (p⁺-type silicon layer) 4 is a n⁺-type (n-type) silicon layer.

Also, a flash memory according to the present embodiment formed by the above manufacturing process has the WN film 9 and the W film 10 (W/WN structure) in the control gate electrode (word line) CG, the select gate layer SG, and the gate contact layer GC.

In a flash memory according to the present embodiment, the n-type polysilicon film 3 of the lower electrode layer 3 and the p-type polysilicon film 82 of the gate contact layer GC are in contact in the EI portion of the gate electrode 3, GC of the MOS transistor Tr. An n-type or p-type impurity of 10¹⁸ cm⁻³ or more is added to each of the n-type polysilicon film 3 and the p-type polysilicon film 82.

Thus, when the peripheral transistor Tr is driven (when a gate voltage is applied), a pn junction formed between the p-type second polysilicon film 82 and the n-type polysilicon film 3 in the gate electrode 3, GC of the MOS transistor Tr is in a forward bias applying state. As a result of the tunnel effect of the pn junction of the p-type and n-type polysilicon films 82, 3 in the forward bias state (occurrence of a forward bias current), the influence of an EI resistance between the lower electrode layer 3 and the gate contact layer GC can be reduced.

In the memory cell transistor MT, the floating gate electrode 4 and the first polysilicon film 6 sandwiching the interpoly dielectric film 5 therebetween are p-type polysilicon. As a result, a depletion layer is formed on at least one of the top surface and undersurface of the interpoly dielectric film 5. As a result, a leak current flowing via the interpoly dielectric film 5 can also be reduced. Also, a flash memory according to the present embodiment is formed so that both of the first polysilicon film 6 and the second polysilicon film 82 forming the gate contact layer GC of the peripheral transistor Tr have the p-type conductivity type. Thus, in contrast to a case when an n-type polysilicon film is provided on a p-type polysilicon film in the gate electrode of the peripheral transistor Tr, a p-type gate structure can be formed without causing depletion between the two polysilicon films 6, 82 forming the gate contact layer GC of the peripheral transistor.

The gate electrode 4, SG of the select gate transistor ST is formed of the lower electrode layer 4 made of p-type semiconductor, the p-type first polysilicon film 6, and the second polysilicon film 82. Thus, no depletion layer is formed in the gate electrode 4, SG of the select gate transistor ST. Therefore, the voltage applied to the lower electrode layer in contact with the gate insulating film 2 can be increased.

The distance between the gate electrode 4, SG of the select gate transistor and the gate electrode 4, CG of the memory cell transistor MT is relatively short. Thus, in contrast to the peripheral transistor Tr, the manufacture of gate electrodes is made easier by using the floating gate electrode (lower electrode layer) 4 made of p-type semiconductor for the select gate transistor ST. On the other hand, by using the gate electrode 3, GC including an n-type semiconductor for the peripheral transistor Tr, surface channel N-type and buried channel P-type MOS transistors conventionally used frequently are formed. As a result, readjustments of transistor characteristics are not needed. Therefore, the manufacture of the gate electrode 3, GC is easy and the peripheral transistor Tr having characteristics identical or more to conventional ones can be formed.

According to the manufacturing method of a nonvolatile semiconductor memory in the first embodiment, as described above, manufacturing costs of the nonvolatile semiconductor memory can be reduced. Also, according to the manufacturing method of a nonvolatile semiconductor memory according to the present embodiment, characteristics of the nonvolatile semiconductor memory can be improved.

### (2) Second Embodiment

A nonvolatile semiconductor memory (for example, a NAND flash memory) according to the second embodiment thereof will be described with reference to FIGS. 8A to 11B. The description of the configuration and functions in the present embodiment that are substantially the same as those in the first embodiment will be described when necessary.

### <Structure>

The structure of a flash memory according to the present embodiment will be described by using FIGS. 8A and 8B.

FIG. 8A shows a cross section structure of a memory cell transistor and a select gate transistor in a NAND flash memory according to the present embodiment along the gate length direction of the transistors.

In FIG. 8A, a structure in which three memory cell transistors are connected in series is shown.

In a formation region of the memory cell transistor MT of a memory cell array region 20, for example, the gate insulating film 2 of the memory cell transistor MT is provided on the p-type silicon region 1. As described above, the gate insulating film 2 is formed by using a single-layer film or a laminated film having a thickness ranging, for example, from 1 nm to 10 nm.

In a memory cell transistor MT, for example, a floating gate electrode 4 made of p-type semiconductor is formed on a gate insulating film 2 in a p-type silicon region 1.

The floating gate electrode 4 is made of polysilicon in the thickness ranging from 30 nm to 120 nm. Boron in the concentration ranging from 10¹⁸ cm⁻³ to 10²² cm⁻³ is added into polysilicon of the floating gate electrode 4.

For example, an interpoly dielectric film 5 is provided on, for example, the floating gate electrode 4. As described above, the interpoly dielectric film 5 is formed by using a single-layer film or a laminated film having a total thickness ranging, for example, from 2 nm to 30 nm.

A control gate electrode CG of the memory cell transistor MT is provided on the interpoly dielectric film 5.

A control gate electrode CG includes a p-type polysilicon film 6 to which boron in the concentration ranging from 10¹⁸ cm⁻³ to 10²² cm⁻³ is added, a WN film 9, and a W film 10 stacked on the WN film 9. The p-type polysilicon film 6 has a thickness ranging, for example, from 5 nm to 100 nm. The WN film 9 has a thickness ranging, for example, from 2 nm to 40 nm. The W film 10 has a thickness ranging, for example, from 10 nm to 100 nm.

A WSi film 9Z having a thickness ranging, for example, from 0.5 nm to 5 nm may be additionally formed as the control gate electrode CG on the opposite side of the W film 10 with respect to the WN film 9 to lower an interface resistance between the WN film 9 and the polysilicon film 6. For example, the undersurface of the WSi film 9Z is in contact with the top surface of the polysilicon film 6 and the top surface of the WSi film 9Z is in contact with the WN film 9.

The present embodiment is different from the first embodiment in that the control gate electrode CG of the memory cell transistor MT includes no p-type polysilicon film in the second layer and has a 1-layer structure of the polysilicon layer 6 between the interpoly dielectric film 5 and a backing film (W/WN film) 9, 10.

A laminated film of polysilicon and WSi, CoSi, NiSi, or tungsten may be used for the control gate electrode CG. When a material other than tungsten is used for the control gate electrode CG, an SiN film as a cap material may not be provided.

An n-type diffusion layer 27 to be a source or drain electrode is formed in the semiconductor region 1 on both sides of the gate electrode 4 of the memory cell transistor MT.

A memory cell of a floating gate type nonvolatile EEPROM (for example, a flash memory) is formed from the floating gate electrode 4, the control gate electrode CG, and a source/drain diffusion layer 27. Further, NAND connection of the memory cell transistors is realized by the n-type diffusion layer 27 as a source/drain electrode being shared by the adjacent memory cell transistors.

In the NAND-connected memory cell transistors MT, like in the first embodiment, select gate transistors ST are provided at both ends of the NAND-connected memory cell transistors MT to select a memory cell block in the NAND-connected memory cell transistors.

The select gate transistor ST is formed by using substantially the same members as those of the memory cell transistor MT.

The present embodiment is different from the first embodiment in that the interpoly dielectric film 5 is eliminated excluding a portion on the word line side (memory cell side) in a gate electrode 4, SG of the select gate transistor ST and the first p-type polysilicon film 6 and a lower electrode layer 4 having substantially the same material as that of the floating gate electrode 4 are directly in contact in the portion of the gate electrode 4, SG on the side (contact plug side) on which the interpoly dielectric film 5 is removed.

FIG. 8B shows a cross section structure of a peripheral transistor in the channel length direction. The peripheral transistor shown in FIG. 8B is a MOS transistor.

A MOS transistor as a peripheral transistor Tr is provided in the p-type silicon region 1 of a peripheral region 21.

A gate electrode 3, GC of a peripheral transistor Tr is provided above the p-type silicon region 1 via the gate insulating film 2. The gate insulating film 2 of the peripheral transistor Tr is formed by using, for example, a film having the same material and the same thickness as those of the gate insulating film 2 of the memory cell transistor MT so that the number of manufacturing processes of flash memories can be reduced.

The gate electrode 3, GC of the MOS transistor Tr has a lower electrode layer 3 made of n-type conductivity type semiconductor formed on the gate insulating film 2. The lower electrode layer 3 has a thickness ranging from 5 nm to 100 nm and is made of n-type (n⁺-type) polysilicon to which phosphorus, arsenic, or antimony in the concentration ranging from 10¹⁸ cm⁻³ to 10²² cm⁻³ is added.

In the present embodiment, a gate contact layer GC is provided on the n-type lower electrode layer 3 of the MOS transistor Tr.

In the MOS transistor as the peripheral transistor Tr included in a flash memory according to the present embodiment, the gate contact layer GC is provided on, for example, the lower electrode layer 3 made of n-type polysilicon, the gate contact layer 3 is formed of the p-type (p⁺-type) polysilicon film 6 to which boron in the concentration ranging from 10¹⁸ cm⁻³ to 10²² cm⁻³ is added, the WN film 9 provided on, for example, the polysilicon film 6 and the W film 10 stacked on the WN film 9. The p-type polysilicon has a thickness ranging from 5 nm to 100 nm. WN film 9 has a thickness ranging from 2 nm to 40 nm. W film 10 has a thickness ranging from 10 nm to 100 nm.

In the MOS transistor Tr, no interpoly dielectric film is interposed between the lower electrode layer 3 and the gate contact layer GC. In other words, the entire top surface of the lower electrode layer 3 and the undersurface of the gate contact layer GC can be in contact.

An n-type impurity layer 16 functioning as an LDD region of a source/drain electrode of the MOS transistor Tr is provided in a surface region of the p-type semiconductor region 1.

A P-type MOS transistor as a peripheral transistor Tr is different only in the conductivity type of the diffusion layer as a source/drain and has a gate electrode structure that is substantially the same as that of an N-type MOS transistor and is provided on a semiconductor substrate (for example, n-type well region).

In the present embodiment, the interpoly dielectric film is removed from most of the gate electrode 4, SG of the select gate transistor ST and the entire gate electrode 3, GC of the peripheral transistor Tr. Accordingly, a contact resistance between the lower electrode layer 4 and the select gate layer SG of a select gate transistor Tr and a contact resistance between the lower electrode layer 3 and the gate contact layer GC of a peripheral transistor Tr can be reduced.

### <Manufacturing Method>

The manufacturing method of a nonvolatile semiconductor memory (for example, a flash memory) according to the second embodiment will be described by using FIGS. 9A to 11C.

In FIGS. 9A to 11C, the manufacturing process of a memory cell transistor, select gate transistor, and peripheral transistor extracting a portion of a memory cell array region 20 and the peripheral region 21 is shown.

As shown in FIGS. 9A to 9C, the n-type and p-type polysilicon layers 3, 4 and the interpoly dielectric film 5 are formed on the gate insulating film 2 by processes that are substantially the same as the processes shown in FIGS. 5A and 5B.

As shown in FIG. 9C, a resist film 93 is formed on the interpoly dielectric film 5. The resist film 93 covering a select gate transistor formation region and the peripheral region 21 is selectively removed to form an opening in the resist film 93 in the select gate transistor formation region and the peripheral region 21. The resist film 93 remains on the interpoly dielectric film 5 in a memory cell transistor formation region in the memory cell array region 20.

For example, etching by the RIE method or the like is performed using the patterned resist mask 93 as a mask. Accordingly, as shown in FIG. 10A, the interpoly dielectric film 5 exposed through the opening is removed. The interpoly dielectric film 5 in the select gate transistor formation region and the peripheral region 21 may be removed by, for example, a wet etching process.

After the interpoly dielectric film 5 being removed, the resist film is removed.

After the interpoly dielectric film 5 in the select gate transistor formation region and the peripheral region 21 being removed, as shown in FIG. 10B, the first polysilicon film 6 included in the control gate electrode is deposited on the remaining interpoly dielectric film 5 and the silicon layers 3, 4 so as to have a thickness ranging from 5 nm to 200 nm.

Impurity ions of boron, BF₂, indium or the like to be a p-type dopant for silicon are injected into the polysilicon film 6 in the range of 10¹³ cm⁻² to 10¹⁷ cm⁻² to form the pt-type polysilicon film 6 to be a component member of the gate electrode of a transistor.

At this point, the p⁺-type polysilicon film 6 can be formed in the memory cell array region 20 and the peripheral region 21 by performing ion implantation on the entire surface of the polysilicon film 6 without applying a resist film for producing differently a p-type or n-type polysilicon to the polysilicon film 6.

As a method of forming the polysilicon film 6 to which a p-type impurity is added, the p-type polysilicon film 6 may be formed on the entire surface of the memory cell array region 20 and the peripheral region 21 by doping in which a B₂H₆ gas or the like is added during deposition of the polysilicon film 6.

After the polysilicon film 6 included in the control gate electrode being formed, as shown in FIG. 10C, the WN film 9 and the W film 10 to be backing films of interconnects (word line/select gate line) are sequentially deposited on the polysilicon film 6 without the second polysilicon film being formed.

In the present embodiment, the formation process of a polysilicon film included in the control gate electrode of a memory cell transistor and the gate contact layer of a peripheral transistor can be reduced and also the lithography process can be reduced. As a result, the influence of contamination of polysilicon by organic matter caused by the lithography process can be reduced. Therefore, the manufacturing method of a flash memory according to the present embodiment can reduce the manufacturing process and therefore, manufacturing costs can be reduced.

As shown in FIGS. 11A and 11B, the cap material 11 and the mask material 12 like, for example, an SiN film is deposited on the W film 10 by processes that are substantially the same as the processes shown in FIGS. 7B and 7C.

An opening is formed by lithography in a corresponding position between memory cell transistors in a resist film (not shown) on the mask material 12.

The mask material 12, the cap material 11, the W film 10, the WN film 9, the p-type polysilicon film 6, the interpoly dielectric film 5, and the floating gate electrode (p-type silicon layer) 4 are sequentially etched by, for example, the RIE method based on the resist film with an opening.

Accordingly, the control gate electrode (word line) CG of the memory cell transistor MT and the floating gate electrode 4 of the memory cell transistor MT are formed.

Next, the source/drain diffusion layer 27 of the memory cell transistor MT is formed, by using, for example, ion implantation, in the p-type silicon region 1 (AA).

After a protective film 13 being formed, an air gap AG is formed between the control gate electrodes CG by the insulating films 14, 15 with poor coverage being deposited.

Subsequently, the gate electrode 4, SG of the select gate transistor ST and the gate electrode 3, GC of the peripheral transistor Tr are formed by lithography and etching in a region on the opposite side of the memory cell side of the select gate transistor formation region and the peripheral region 21.

In the present embodiment, the polysilicon film 6 is formed from a polysilicon doped with the same impurity in the select gate transistor ST and the peripheral transistor Tr. Thus, there arises almost no difference in etching rate between silicon films resulting from doping (different conductivity types) between the select gate transistor ST and the peripheral transistor Tr so that more uniform etching can be performed when a gate electrode is processed.

An n-type diffusion layer 27z, 16 to be a source/drain electrode on the opposite side of the memory cell side of the select gate transistor ST and a source/drain electrode of the peripheral transistor Tr is substantially simultaneously formed in the p-type semiconductor region 1. Also, a p-type diffusion layer as a source/drain of a P-type MOS transistor Tr is formed in an n-type well using a gate electrode formed substantially simultaneously with an N-type MOS transistor as a mask in a process that is different from the formation process of an n-type diffusion layer.

After sidewall insulating film (not shown) being formed, an inter-layer insulating film, contact plug, and interconnects are sequentially formed on the semiconductor region 1 by using known technology.

With the above processes, a flash memory according to the present embodiment is produced.

In the manufacturing method of a flash memory according to the present embodiment, except that the polysilicon layer (lower electrode layer) 3 deposited simultaneously with the floating gate electrode included in the MOS transistor Tr in the peripheral region 21 is an n⁺-type (n-type) conductivity type, the gate electrode of each transistor is formed in such a way that the floating gate electrode 4 and the control gate electrode CG of the memory cell transistor MT and the lower electrode layer 4 and the select gate layer SG of the gate electrode of the select gate transistor ST in the memory cell array region 20 and the gate contact layer GC of the gate electrode of the MOS transistor Tr in the peripheral region 21 include the p-type silicon layers 4, 6. The WN/W films 9, 10 are formed on the p-type polysilicon film 6 in the gate electrode of each of the transistors MT, ST, Tr.

In the manufacturing method of a flash memory according to the present embodiment, the interpoly dielectric film 5 is provided only in the whole space between the floating gate electrode 4 and the control gate electrode CG of the memory cell transistor MT and a portion of the space between the lower electrode layer 4 and the select gate layer SG of the select gate transistor ST and the interpoly dielectric film 5 is removed from most of the space between the lower electrode layer 4 and the select gate layer SG of the select gate transistor ST and in the peripheral region 21 (in the gate electrode of the peripheral transistor Tr). The interpoly dielectric film 5 is not present in the gate electrode 3, GC of the peripheral transistor Tr. Incidentally, like the peripheral transistor Tr, the gate electrode 4, SG of the select gate transistor ST may not include the interpoly dielectric film.

Accordingly, the contact area of the lower electrode layer 4 and the select gate layer SG of the select gate transistor ST and the contact area of the lower electrode layer 3 and the gate contact layer GC of the peripheral transistor Tr can be increased so that the contact resistance in the gate electrode of each transistor ST, Tr can be reduced.

In the peripheral transistor Tr included in a flash memory according to the present embodiment, the p-type polysilicon film 6 in the gate contact layer GC and the n-type silicon layer 3 as a lower electrode layer are formed so as to be in contact with each other. An impurity of 10¹⁸ cm⁻³ or more is added to each of the p-type polysilicon film 6 and the n-type silicon layer 3.

When a voltage is applied to the gate electrode 3, GC of the peripheral transistor Tr, a pn junction formed from the p-type polysilicon film 6 and the n-type silicon layer 3 is in a forward bias state. As a result of the tunnel effect of the pn junction formed from the p-type and n-type polysilicon films in the forward bias state, the influence of the contact resistance (interface resistance) between the lower electrode layer 3 and the gate contact layer GC can be reduced.

According to the above manufacturing method, the gate contact layer GC of the peripheral transistor Tr includes the 1-layer polysilicon film 6 and the polysilicon film 6 is formed so as to have a p-type conductivity type. Therefore, possible depletion between polysilicon films that may arise for a 2-layer polysilicon film of an n-type polysilicon film and a p-type polysilicon film can be avoided so that the p-type gate contact layer GC can be formed in the gate electrode of the peripheral transistor Tr.

According to the manufacturing method of a nonvolatile semiconductor memory in the second embodiment, as described above, manufacturing costs can be reduced like in the first embodiment.

### (3) Third Embodiment

A nonvolatile semiconductor memory (for example, a NAND flash memory) according to the third embodiment will be described with reference to FIGS. 12A to 15B. The description of the configurations and functions in the present embodiment that are substantially the same as those in the first and second embodiments will be described when necessary.

### <Structure>

The structure of a flash memory according to the present embodiment will be described by using FIGS. 12A and 12B.

FIG. 12A shows a cross section structure of a memory cell transistor and a select gate transistor along the gate length direction of the transistors in a flash memory according to the present embodiment. In FIG. 12A, a structure in which three memory cell transistors MT are connected in series is shown.

In a memory cell array region 20, for example, the gate insulating film 2 of the memory cell transistor MT is provided on the p-type semiconductor region 1. As described above, the gate insulating film 2 is formed by using a single-layer film or a laminated film having a thickness ranging, for example, from 1 nm to 10 nm.

In a memory cell transistor MT, for example, a floating gate electrode 4 made of p-type semiconductor is formed on a gate insulating film 2 on the silicon region 1.

The floating gate electrode 4 is made of p-type polysilicon to which boron is added in the concentration ranging from 10¹⁸ cm⁻³ to 10²² cm⁻³. The floating gate electrode 4 has a thickness ranging from 30 nm to 120 nm.

An interpoly dielectric film 5 is provided on the floating gate electrode 4. As described above, the interpoly dielectric film 5 is formed by using a single-layer film or a laminated film having a total thickness ranging, for example, from 2 nm to 30 nm.

A control gate electrode CG of the memory cell transistor MT is provided on the interpoly dielectric film 5.

The control gate electrode CG includes a p-type (p⁺-type) first polysilicon film 6 to which boron is added in the concentration ranging, for example, from 10¹⁸ cm⁻³ to 10²² cm⁻³, a p-type (p⁺-type) second polysilicon film 83 to which boron is added in the concentration ranging, for example, from 10¹⁸ cm⁻³ to 10²² cm⁻³ on the film 6, for example, a WN film 9 on the polysilicon film 83, and a W film 10 stacked on the WN film 9. The first polysilicon film 6 has a thickness ranging, for example, from 5 nm to 100 nm. The second polysilicon film 83 has a thickness ranging, for example, from 5 nm to 100 nm. The WN film 9 has a thickness ranging, for example, from 2 nm to 40 nm. The W film 10 has a thickness ranging, for example, from 10 nm to 100 nm.

A WSi film 9Z having a thickness ranging, for example, from 0.5 nm to 5 nm may be additionally formed as the control gate electrode CG on the opposite side of the W film 10 with respect to the WN film 9 to lower an interface resistance between the WN film 9 and the polysilicon film 83. For example, the undersurface of the WSi film 9Z is in contact with the top surface of the polysilicon film 83 and the top surface of the WSi film 9Z is in contact with the WN film 9.

The control gate electrode CG may have a laminate film of polysilicon and WSi, CoSi, NiSi, or tungsten. If the control gate electrode CG has a structure other than tungsten (for example, silicide), the cap material 11 may not be provided on the control gate electrode CG.

N-type diffusion layers 27 to be a source/drain electrode of the transistor MT are formed in the silicon region 1 at both ends in the channel length direction of the gate electrode 4 of these memory cell transistors MT.

A memory cell of a floating gate type nonvolatile EEPROM (for example, a flash memory) is formed from the memory cell transistor MT including the floating gate electrode 4, the control gate electrode CG, and the n-type diffusion layer 27 as a source/drain electrode. NAND connection of the memory cell transistors MT is realized by the n-type diffusion layer 27 of the memory cell transistor MT being shared by the adjacent memory cell transistors MT.

To select a memory cell block of the NAND-connected memory cell transistors MT as described above, select gate transistors ST are provided at both ends of the NAND-connected memory cell transistors MT.

In the present embodiment, an interpoly dielectric film 5 and a first p-type polysilicon film 6 in the select gate layer SG are eliminated excluding a portion on the word line side (memory cell side) of the select gate transistor ST. Then, in the present embodiment, a lower electrode layer 4 made of p-type polysilicon layer and a second p-type polysilicon film 83 in the select gate layer SG are directly in contact in the portion where the interpoly dielectric film 5 and a first polysilicon film 6 are eliminated.

FIG. 12B shows a cross section structure in the channel length direction of a peripheral transistor. The peripheral transistor shown in FIG. 12B is a MOS transistor.

In the present embodiment, a gate contact layer GC includes the p-type polysilicon film 83, instead of an n-type polysilicon film, in a gate electrode 3, GC of the MOS transistor as a peripheral transistor Tr.

The MOS transistor Tr as a peripheral transistor Tr is provided in a p-type semiconductor region 1 of a peripheral region 21.

A gate electrode 3, GC of the peripheral transistor Tr is provided above the p-type silicon region 1 via a gate insulating film 2. The gate insulating film 2 of the peripheral transistor Tr is formed by using, for example, a film having the same material and the same thickness as those of the gate insulating film 2 of the memory cell transistor MT so that the number of manufacturing processes of flash memories can be reduced.

The gate electrode 3, GC of the peripheral transistor Tr has a lower electrode layer 3 provided on the gate insulating film 2 and made of n-type semiconductor. The lower electrode layer 3 has a thickness ranging from 5 nm to 100 nm. The lower electrode layer 3 is made of n-type polysilicon to which, for example, phosphorus, arsenic, or antimony is added in the concentration ranging from 10¹⁸ cm⁻³ to 10²² cm⁻³.

In the peripheral transistor MT in the present embodiment, the gate contact layer GC is stacked on the lower electrode layer 3 without being interposed by an interpoly dielectric film therebetween. That is, the entire top surface of the lower electrode layer 3 and the undersurface of the gate contact layer GC are in contact.

The gate contact layer GC includes the p-type second polysilicon film 83 to which boron in the concentration ranging from 10¹⁸ cm⁻³ to 10²² cm⁻³, a WN film 9, and a W film 10 stacked on the WN film 9. The p-type second polysilicon film 83 has a thickness ranging, for example, from 5 nm to 100 nm. The WN film 9 has a thickness ranging, for example, from 2 nm to 40 nm. The W film 10 has a thickness ranging, for example, from 10 nm to 100 nm.

The gate contact layer GC of the peripheral transistor Tr does not include the first p-type polysilicon film 6 included in the control gate electrode CG of the memory cell transistor MT.

An n-type diffusion layer 16 functioning as an LDD region of a source and drain electrode of the MOS transistor Tr is provided on the surface of the p-type silicon region 1 of the peripheral region 21.

A P-type MOS transistor as a peripheral transistor Tr is different only in the conductivity type of the diffusion layer as a source/drain and has a gate electrode structure that is substantially the same as that of an N-type MOS transistor and is provided on a semiconductor substrate (for example, n-type well region).

Also when, like a flash memory according to the present embodiment, the memory cell transistor MT, the select gate transistor ST, and the peripheral transistor (for example, a MOS transistor) Tr have a structure shown in FIGS. 12A and 12B, effects similar to those of each embodiment described above can be obtained.

### <Manufacturing Method>

The manufacturing method of a NAND flash memory according to the third embodiment will be described by using FIGS. 13A to 15B.

In FIGS. 13A to 15B, the manufacturing process of a memory cell transistor, select gate transistor, and peripheral transistor extracting a portion of a memory cell array region 20 and the peripheral region 21 is shown.

As shown in FIGS. 13A and 13B, the n-type and p-type polysilicon layers 3, 4 are formed on the gate insulating film 2 in the memory cell array region 20 and the peripheral region 21 respectively by a process similar to the above manufacturing process.

As shown in FIG. 13C, the interpoly dielectric film 5 is formed on the polysilicon layers 3, 4 by a process similar to the above manufacturing process. The first polysilicon film 6 is thinly formed on the interpoly dielectric film 5.

A resist film 92 is formed on the polysilicon film 6 so as to have an opening in a select gate transistor formation region and the peripheral region 21.

The first polysilicon film 6 and the interpoly dielectric film 5 are etched until the polysilicon layers 3, 4 to be lower electrode layers are reached in the select gate transistor formation region and the peripheral region 21 using the resist film 92 with an opening as a mask.

Accordingly, as shown in FIG. 14A, a region where the top surface of the polysilicon layers 3, 4 is exposed in the select gate transistor formation region and the peripheral region 21 is formed. After the etching, the resist film is removed.

As shown in FIG. 14B, the polysilicon film 83 is deposited so as to have a thickness of 5 nm to 200 nm (or 5 nm to 100 nm).

Here, for example, the non-doped second polysilicon film 83 is formed on the first polysilicon film 6 on the interpoly dielectric film 5 in a memory cell transistor formation region in the memory cell array region 20. In the select gate transistor formation region and the peripheral region 21, on the other hand, the second polysilicon film 83 is formed on the polysilicon layers 3, 4 to be lower electrode layers.

Impurity ions to be a p-type dopant like, for example, boron, BF₂, and indium (In) are injected into the second polysilicon film 83 in the range of 10¹³ cm⁻² to 10¹⁶ cm⁻² to form the p-type polysilicon film 83 to form a pt-type gate.

At this point, the pt-type polysilicon film 83 can be formed by performing ion implantation on the entire surface of the polysilicon film 83 without applying a resist film for producing differently a p-type and n-type polysilicon film to the polysilicon film 83.

By depositing the p-type polysilicon film 83 as described above, one lithography process can be reduced and thus, manufacturing costs of flash memories can be reduced.

Also, the influence of contamination of polysilicon by organic matter that may be caused by the lithography process can be reduced.

Subsequently, as shown in FIG. 14C, the WN film 9 and the W film 10 to be backing interconnects of the control gate electrode (word line) are deposited on the p-type polysilicon film 83 by processes that are substantially the same as the above processes.

As shown in FIG. 15A, the cap material/mask material 11, 12 are deposited on the W film 10 in the memory cell array region 20 and the peripheral region 21.

The mask material 12 is patterned by lithography so that an opening is formed in a region between memory cell transistors in the memory cell formation region of the memory cell array region 20 and the mask material 12, the cap material 11, the W film 10, the WN film 9, the second polysilicon film 83, the first polysilicon film 6, the interpoly dielectric film 5, and the floating gate electrode (p-type silicon film) 4 are sequentially etched by, for example, the RIE method.

Accordingly, the floating gate electrode 4 and the control gate electrode (word line) CG of the memory cell transistor MT are formed.

Next, a source/drain diffusion layer 27 of the memory cell transistor MT is formed in the p-type silicon region 1.

After a protective film 13 being formed, an air gap AG is formed between the adjacent control gate electrodes CG by the insulating films 14, 15 being deposited.

Subsequently, a gate electrode 4, SG of the select gate transistor ST and the gate electrode 3, GC of the peripheral transistor Tr are formed by gate processing of component members of a gate electrode through lithography and etching in a region on the opposite side of the memory cell side of the select gate transistor formation region and the peripheral region 21.

When gate processing of the select gate transistor ST and peripheral transistor Tr is performed, the second polysilicon film 83 is formed from a silicon of the same conductivity type (here, the p type) in the select gate transistor in the memory cell array region 20 and the peripheral transistor 21 in the peripheral region 21 and therefore, there arises no difference in etching rate due to the difference of doped impurities so that uniform etching can be performed.

Subsequently, as shown in FIGS. 12A and 12B, source/drain diffusion layers 16, 27z are formed in the region on the opposite side of the memory cell side of the select gate transistor formation region and the peripheral region 21.

A p-type diffusion layer as a source/drain of a P-type MOS transistor Tr is formed in an n-type well region using a gate electrode formed substantially simultaneously with an N-type MOS transistor as a mask in a process that is different from the formation process of an n-type diffusion layer.

After a sidewall insulating film (not shown) being formed, an inter-layer insulating film, contact plug, and interconnects are sequentially formed on the silicon region 1 by using known technology.

With the above processes, a flash memory according to the present embodiment is produced.

In a flash memory according to the present embodiment and the manufacturing method thereof, except that the polysilicon layer (lower electrode layer) 3 deposited simultaneously with the floating gate electrode included in the MOS transistor Tr in the peripheral region 21 is an n⁺-type (n-type) conductivity type, the gate electrode of each transistor MT, ST, Tr is formed in such a way that the floating gate electrode 4 and the control gate electrode CG of the memory cell transistor MT and the lower electrode layer 4 and the select gate layer SG of the gate electrode of the select gate transistor ST in the memory cell array region 20 and the gate contact layer GC of the gate electrode of the MOS transistor Tr in the peripheral region 21 include a p-type silicon layer. The WN film 9 and the W film 10 are provided on the p-type silicon film 83 in an upper portion of the gate electrode of each of the transistors MT, ST, Tr.

In the present embodiment, the interpoly dielectric film 5 is included between the floating gate electrode 4 and the control gate electrode CG of the memory cell transistor MT and in a portion between the lower electrode layer 4 and the select gate electrode SG of the select gate transistor ST in the memory cell array region 20. The control gate electrode CG of the memory cell transistor MT and the select gate layer SG of the select gate transistor ST includes the first and second p-type polysilicon films 6, 83.

On the other hand, the gate electrode of the peripheral transistor Tr according to the present embodiment in the peripheral region 21 does not include the first polysilicon film 6 and the interpoly dielectric film 5 and includes the second polysilicon film 83 on the lower electrode layer 3.

In the present embodiment, the lower electrode layers 3, 4 and the p-type second polysilicon film 83 are in contact in the select gate transistor ST and the peripheral transistor Tr.

With most or all of the interpoly dielectric film 5 being removed from inside the gate electrode in the select gate transistor ST and the peripheral transistor Tr like in the present embodiment, the contact area of the p-type second polysilicon film 83 of an upper electrode and the lower electrode layers (silicon layers) 3, 4 can be increased.

In the gate electrode of the MOS transistor, an impurity of 10¹⁸ cm⁻³ or more is added to each of the n-type silicon layer 3 as a lower electrode layer and the p-type polysilicon film 83 of the gate contact layer GC. When a drive voltage is applied to the gate electrode of the peripheral transistor Tr, a pn junction formed from the p-type polysilicon film 83 and the n-type silicon layer 3 is in a forward bias state. As a result of the tunnel effect of the pn junction formed from the p-type and n-type polysilicons in the forward bias state, the influence of the interface resistance (contact resistance) between the lower electrode layer 3 and the gate contact layer GC of the peripheral transistor Tr can be reduced.

According to the above manufacturing method, the gate contact layer GC of the peripheral transistor Tr is formed in such a way that the p-type polysilicon film 83 is directly in contact with the lower electrode layer 3.

Thus, depletion of silicon films that may arise when two polysilicon films (for example, a p-type polysilicon film and an n-type polysilicon film thereon) are provided in the gate contact layer GC can be avoided and the p-type gate contact layer GC can be formed in the gate electrode of the peripheral transistor Tr.

According to the manufacturing method of a nonvolatile semiconductor memory in the third embodiment, as described above, manufacturing costs can be reduced like in each embodiment described above.

### (4) Fourth Embodiment

A nonvolatile semiconductor memory (for example, a NAND flash memory) according to the fourth embodiment will be described with reference to FIGS. 16A to 18C. The description of the configurations and functions in the present embodiment that are substantially the same as those in the first to third embodiments will be described when necessary.

### <Structure>

The structure of a flash memory according to the present embodiment will be described by using FIGS. 16A and 16B.

FIG. 16A shows a cross section structure of a memory cell transistor MT and a select gate transistor ST in a NAND flash memory according to the present embodiment along the gate length direction of the transistors. In FIG. 16A, a structure in which three memory cell transistors are connected in series is shown.

In a memory cell array region 20, for example, the gate insulating film 2 of the memory cell transistor MT is provided on the p-type semiconductor region 1. As described above, the gate insulating film 2 is formed by using a single-layer film or a laminated film having a thickness ranging, for example, from 1 nm to 10 nm.

The floating gate electrode 4 made of a p-type semiconductor is provided on the gate insulating film 2. The floating gate electrode 4 is made of p-type polysilicon to which boron is added in the concentration ranging, for example, from 10¹⁸ cm⁻³ to 10²² cm⁻³. The floating gate electrode 4 has a thickness ranging, for example, from 30 nm to 120 nm.

An interpoly dielectric film 5 is provided on the floating gate electrode 4. As described above, the interpoly dielectric film 5 is formed by using a single-layer film or a laminated film having a total thickness ranging, for example, from 2 nm to 30 nm.

A control gate electrode CG of the memory cell transistor MT is provided on the interpoly dielectric film 5.

The control gate electrode CG includes a p-type (p⁺-type) first polysilicon film 6 to which boron is added in the concentration ranging, for example, from 10¹⁸ cm⁻³ to 10²² cm⁻³, and which is provided on the interpoly dielectric film 5, a WN film 9 on the polysilicon film 6, and a W film 10 stacked on the WN film 9. The first polysilicon film 6 has a thickness ranging, for example, from 5 nm to 100 nm. The WN film 9 has a thickness ranging, for example, from 2 nm to 40 nm. The W film 10 has a thickness ranging, for example, from 10 nm to 100 nm.

In a gate electrode 4, CG of a memory cell transistor MT included in a flash memory according to the present embodiment, a control gate electrode CG includes only one layer of a p-type polysilicon layer 6 and a WN layer 9 is directly stacked on the 1-layer polysilicon film 6 included in the control gate electrode CG.

An interface resistance between the first polysilicon film 6 and the WN film 9 may be lowered by additionally forming a WSi film 9Z having a thickness ranging, for example, from 0.5 nm to 5 nm between the first polysilicon film 6 and the WN film 9. For example, the undersurface of the WSi film 9Z is in contact with the top surface of the first polysilicon film 6 and the top surface of the WSi film 9Z is in contact with the WN film 9.

The control gate electrode CG may have a laminated film of silicon and WSi, CoSi, NiSi, or tungsten. If the control gate electrode CG has a structure other than tungsten/polysilicon structure (for example, polycide), the cap material 11 may not be provided on the control gate electrode CG.

N-type diffusion layers 27 to be a source/drain electrode of the memory cell transistor MT are formed in the semiconductor region 1 at both ends of the floating gate electrode 4 of these memory cell transistors MT.

A memory cell of a floating gate type nonvolatile EEPROM (for example, a flash memory) is formed from the memory cell transistor MT including the floating gate electrode 4, the control gate electrode CG, and the n-type diffusion layer 27 as a source/drain. NAND connection of the memory cell transistors MT is realized by the n-type diffusion layer 27 of the memory cell transistor MT being shared by the adjacent memory cell transistors MT.

To select a memory cell block in NAND-connected memory cell transistors, as described above, a select gate transistor is provided at one end and the other end of the NAND-connected memory cell transistors.

In the present embodiment, a p-type first polysilicon film 6 and an interpoly dielectric film 5 are eliminated excluding a portion on the word line side (memory cell side) in a gate electrode 4, SG of a select gate transistor ST. A lower electrode layer 4 made of the same material as that of the floating gate electrode 4 and a WN film 9 are directly in contact in a portion from which the p-type first polysilicon film 6 and the interpoly dielectric film 5 are eliminated in the gate electrode 4, SG of the select gate transistor ST. Thus, the structure of the select gate transistor ST in the present embodiment is different from the structure of the select gate transistors in the above embodiments.

FIG. 16B shows a cross section structure in the channel length direction of a peripheral transistor. The peripheral transistor shown in FIG. 16B is a MOS transistor.

The MOS transistor as a peripheral transistor Tr is provided in a p-type silicon region 1.

A gate electrode 3, GC of the peripheral transistor Tr is provided above the p-type silicon region 1 via a gate insulating film 2.

The gate insulating film 2 of the peripheral transistor Tr is formed by using a film having the same material and the same thickness as those of the material and thickness of insulating film 2 of memory cell transistor MT so that the number of manufacturing processes of flash memories can be reduced.

The MOS transistor as a peripheral transistor Tr includes a lower electrode layer 3 of n-type semiconductor formed on the gate insulating film 2. The lower electrode layer 3 is made of a polysilicon layer having a thickness ranging from 5 nm to 100 nm. The polysilicon layer as the lower electrode layer 3 has, for example, phosphorus, arsenic, or antimony in the concentration ranging from 10¹⁸ cm⁻³ to 10²² cm⁻³ added thereto.

The MOS transistor as a peripheral transistor Tr included in a flash memory according to the present embodiment includes a gate contact layer (upper electrode layer) GC formed by the WN film 9 stacked on the lower electrode layer 3 made of n-type polysilicon layer and a W film 10 stacked on the WN film 9. WN film 9 has a thickness ranging, for example, from 2 nm to 40 nm. W film 10 has a thickness ranging, for example, from 10 nm to 100 nm

An interface resistance between the WN film 9 and the lower electrode layer 3 (n-type polysilicon film) may be lowered by additionally forming a WSi film 9Z in the range of, for example, 0.5 nm to 5 nm on the opposite side of the W film 10 with respect to the WN film 9. For example, the undersurface of the WSi film 9Z is in contact with the top surface of the lower electrode layer 3 (n-type polysilicon film) and the top surface of the WSi film 9Z is in contact with the WN film 9.

In a peripheral region 21, an n-type diffusion layer 16 functioning as an LDD region of a source and drain of the MOS transistor Tr is provided in a surface region of the p-type silicon region 1.

A P-type MOS transistor as a peripheral transistor Tr is different only in the conductivity type of the diffusion layer as a source/drain and has a gate electrode structure that is substantially the same as that of an N-type MOS transistor and is provided on a semiconductor substrate (for example, on n-type well region).

Also when, like a flash memory according to the present embodiment, the memory cell transistor MT, the select gate transistor ST, and the peripheral transistor (for example, a MOS transistor) Tr have a structure shown in FIGS. 16A and 16B, effects similar to those of each embodiment described above can be obtained.

### <Manufacturing Method>

The manufacturing method of a NAND flash memory according to the fourth embodiment will be described by using FIGS. 17A to 18C.

In FIGS. 17A to 18C, the manufacturing process of a memory cell transistor, select gate transistor, and peripheral transistor extracting a portion of a memory cell array region 20 and the peripheral region 21 is shown.

As shown in FIGS. 17A and 17B, the gate insulating film 2 is formed in the p-type silicon region 1 of the memory cell array region 20 and the peripheral region 21 by processes that are substantially the same as the above processes. Then, the p-type polysilicon layer 4 is formed on the gate insulating film 2 in the memory cell array region 20 and the n-type polysilicon layer 3 is formed on the gate insulating film 2 in the peripheral region 21.

As shown in FIG. 17C, the interpoly dielectric film 5 and the first p-type polysilicon film 6 are deposited on the polysilicon layers 3, 4 in the memory cell array region 20 and the peripheral region 21 by processes that are substantially the same as the above processes.

After a resist film 92 being applied onto the first polysilicon film 6, an opening is formed in a resist film 92 by lithography and etching in a select gate transistor formation region and the peripheral region 21.

As shown in FIG. 17D, the first polysilicon film 6 and the interpoly dielectric film 5 are etched until the polysilicon layers 3, 4 to form lower electrode layers of the select gate transistor and peripheral transistor in the select gate transistor formation region and the peripheral region 21 are reached. Accordingly, the first polysilicon film 6 and the interpoly dielectric film 5 are selectively removed from the select gate transistor formation region and the peripheral region 21 and the first polysilicon film 6 and the interpoly dielectric film 5 remain in a memory cell transistor formation region.

As shown in FIG. 18A, the WN film 9 is deposited on the polysilicon film 6 in the memory cell transistor formation region, the polysilicon layer 4 in the select gate transistor formation region, and the polysilicon layer 3 in the peripheral region 21. The W film 10 is deposited on the WN film 9. The cap material 11 and the mask material 12 are sequentially deposited on the W film 10.

By forming the WN film 9 on the first polysilicon film 6 of the control gate electrode as described above, the formation process of a polysilicon film of the control gate electrode (and the upper electrode layer) and one lithography process can be cut back. Also, the influence of contamination of polysilicon by organic matter that may be caused by the additional lithography process can be reduced. Thus, according to the present embodiment, the manufacturing process can be decreased and therefore, manufacturing costs can be reduced.

In addition, with the WN film 9 being formed on the first polysilicon film 6, siliciding of the polysilicon film 6 and the W film 10 can be prevented and the disappearance of the polysilicon film 6 is not caused.

Subsequently, as shown in FIGS. 18B and 18C, an opening is formed in a region between memory cell transistors by lithography and the mask material 12, the cap material 11, the W film 10, the WN film 9, the first polysilicon film 6, the interpoly dielectric film 5, and the floating gate electrode 4 are etched by the RIE method by executing processes that are substantially the same as the above processes. Accordingly, the control gate electrode CG and the floating gate electrode 4 of the memory cell transistor MT are formed.

The n-type diffusion layer 27 as a source/drain electrode of the memory cell transistor MT is formed by, for example, ion implantation, in the p-type semiconductor region 1 of memory cell array region 20.

After a protective film 13 being formed, an air gap AG is formed between the memory cell transistors MT by the insulating films 14, 15 being deposited on the mask material 12.

Subsequently, gate electrodes of the select gate transistor ST and the peripheral transistor Tr are formed by gate processing of component members of the gate electrodes of the select gate transistor ST and the peripheral transistor Tr (MOS transistor) through lithography and etching in a region on the opposite side of the memory cell side of the select gate transistor formation region and the peripheral region 21.

Because the select gate layer SG of the select gate transistor ST and the gate contact layer GC of the peripheral transistor Tr are formed of the WN film 9 and the W film 10, there arises almost no difference in etching rate between the select gate transistor ST and the peripheral transistor Tr so that the select gate transistor ST and the peripheral transistor Tr can substantially simultaneously be processed by more uniform etching.

The sources/drains 27z, 16 of the transistors ST, Tr made of an n-type diffusion layer is formed by, for example, ion implantation, in a region on the opposite side of the memory cell side of the select gate transistor formation region and a sources/drain region of the peripheral transistor Tr.

A p-type diffusion layer as a source/drain of a P-type MOS transistor Tr is formed in an n-type well region using a gate electrode formed substantially simultaneously with an N-type MOS transistor as a mask in a process that is different from the formation process of an n-type diffusion layer.

Subsequently, an inter-layer insulating film, contact plug, and interconnects are sequentially formed as described above by using known technology to form a flash memory according to the present embodiment.

In a flash memory according to the present embodiment and the manufacturing process thereof, except that the lower electrode layer 3 of the peripheral transistor Tr (for example, a MOS transistor) formed in the peripheral region 21 is made of n-type (n⁺-type) polysilicon, the floating gate electrode 4 and the control gate electrode CG of the memory cell transistor MT and the lower electrode layer 4 and the select gate layer SG of the select gate transistor ST have a p-type gate structure formed by using pt-type polysilicon. No p-type polysilicon film is provided in the gate electrode 3, GC of the peripheral transistor Tr.

A laminated structure of the WN film 9 and the W film 10 is provided in the control gate electrode CG of the memory cell transistor MT, the select gate layer SG of the select gate transistor ST, and the gate contact layer GC of the peripheral transistor Tr.

In the present embodiment, the memory cell transistor MT includes the interpoly dielectric film 5 and the first polysilicon film 6, the select gate transistor ST includes the interpoly dielectric film 5 and the first polysilicon film in a portion on the memory cell side in the gate electrode, and the WN film 9 is directly stacked on the first polysilicon film 6.

The WN film 9 is stacked on the lower electrode layer 4 and is directly in contact with the p-type silicon layer 4 as the lower electrode layer 4 in a portion in the gate electrode of the select gate transistor ST where neither interpoly dielectric film nor first polysilicon film is included.

The MOS transistor as the peripheral transistor Tr includes neither interpoly dielectric film nor first polysilicon film in the gate electrode 3, GC, and the WN film 9 is stacked on the lower electrode layer 3 and is directly in contact with the n-type polysilicon layer 3 as the lower electrode layer 3.

Thus, a flash memory according to the present embodiment is different from the above embodiments in that the lower electrode layers 4, 3 and the WN film 9 in the gate electrode are directly in contact in the select transistor ST and the peripheral transistor Tr.

According to the present embodiment, the contact area of the lower electrode layers 4, 3 and the upper electrode layer SG, GC of the select gate transistor ST and peripheral transistor Tr can be increased when compared with the gate electrode in an EI structure by the interpoly dielectric film being removed from most of the gate electrode 4, SG of the select gate transistor ST and the entire gate electrode 3, GC of the peripheral transistor Tr so that the influence of an interface resistance between component members of the gate electrode can be reduced.

According to a nonvolatile semiconductor memory in the present embodiment and the manufacturing method thereof, as described above, manufacturing costs of the nonvolatile semiconductor memory can be reduced. Also, according to a nonvolatile semiconductor memory in the present embodiment and the manufacturing method thereof, characteristics of the nonvolatile semiconductor memory can be improved.

### (5) Fifth Embodiment

A nonvolatile semiconductor memory (for example, a NAND flash memory) according to the fifth embodiment will be described with reference to FIGS. 19A to 20C. The description of configurations and functions in the present embodiment that are substantially the same as those in the first to fourth embodiments will be described when necessary.

### <Structure>

The structure of a flash memory according to the present embodiment will be described by using FIGS. 19A and 19B.

FIG. 19A shows a cross section structure of a memory cell transistor MT and a select gate transistor ST in a NAND flash memory according to the present embodiment along the gate length direction of the transistors.

In FIG. 19A, a structure in which three memory cell transistors MT are connected in series is shown.

In a memory cell array region 20, for example, the gate insulating film 2 of the memory cell transistor MT is provided on the p-type silicon region 1. As described above, the gate insulating film 2 is formed by using a single-layer film or a laminated film having a total thickness ranging, for example, from 1 nm to 10 nm.

The floating gate electrode 4 made of a p-type semiconductor is provided on the gate insulating film 2.

The floating gate electrode 4 is formed of p-type polysilicon to which boron is added in the concentration ranging, for example, from 10¹⁸ cm⁻³ to 10²² cm⁻³. The floating gate electrode 4 has a thickness ranging from 30 nm to 120 nm.

An interpoly dielectric film (inter-gate insulating film) 5 is provided on the floating gate electrode 4. As described above, the interpoly dielectric film 5 is formed by using a single-layer film or a laminated film having a total thickness ranging, for example, from 2 nm to 30 nm.

A control gate electrode CG is provided on the interpoly dielectric film 5.

The control gate electrode CG includes a p-type (p⁺-type) first polysilicon film 6 to which boron is added in the concentration ranging, for example, from 10¹⁸ cm⁻³ to 10²² cm⁻³, and which is provided on the interpoly dielectric film 5, a WN film 9 stacked on the polysilicon film 6, and a W film 10 stacked on the WN film 9. The first polysilicon film 6 has a thickness ranging, for example, from 5 nm to 100 nm. The WN film 9 has a thickness ranging, for example, from 2 nm to 40 nm. The W film 10 has a thickness ranging, for example, from 10 nm to 100 nm.

The WN film 9 and the W film 10 become backing interconnects of the control gate electrode CG used as the word lines WL. The WN film 9 functions, for example, as a barrier metal.

An interface resistance between the first polysilicon film 6 and the WN film 9 may be lowered by additionally forming a WSi film 9Z having a thickness ranging, for example, from 0.5 nm to 5 nm between the first polysilicon film 6 and the WN film 9. For example, the undersurface of the WSi film is in contact with the top surface of the first polysilicon film 6 and the top surface of the WSi film is in contact with the WN film 9.

The control gate electrode CG including a laminated film formed of silicon and WSi, CoSi, NiSi, or a tungsten may be used for the memory cell transistor MT. If the control gate electrode CG has a structure other than tungsten, the cap material 11 may not be provided on the control gate electrode CG.

N-type diffusion layers 27 to be a source electrode or drain electrode of the memory cell transistor MT are formed in the p-type silicon region 1 at both ends in the channel length direction of the gate electrode 4 of these memory cell transistors MT.

A memory cell of a floating gate type nonvolatile EEPROM (for example, a flash memory) is formed from the memory cell transistor MT including a floating gate electrode 4, a control gate electrode CG, and an n-type diffusion layer 27 as a source/drain. NAND connection of the memory cell transistors MT is realized by the n-type diffusion layer 27 of the memory cell transistor MT being shared by the adjacent memory cell transistors MT.

Like in each of the above embodiments, a select gate transistor ST is formed at one and the other end of the NAND-connected memory cell transistors MT to select a memory cell block.

In the present embodiment, the select gate transistor ST includes a lower electrode layer 4 formed substantially simultaneously by using the same material as that of the floating gate electrode 4, an interpoly dielectric film 5 provided on the lower electrode layer 4 and having an opening (EI portion), and a select gate layer SG provided on the lower electrode layer 4 and the interpoly dielectric film 5. The select gate layer SG is directly in contact with the lower electrode layer 4 via the opening of the interpoly dielectric film 5.

The select gate layer SG includes substantially the same material as that of component members included in the control gate electrode CG. The select gate layer SG includes a p-type first polysilicon film 6 to which boron in the concentration ranging, for example, from 10¹⁸ cm⁻³ to 10²² cm⁻³ is added, a WN film 9 stacked on the polysilicon film 6, and a W film 10 stacked on the WN film 9. The polysilicon film 6 has an opening in a position corresponding to an opening in the interpoly dielectric film 5. The p-type first polysilicon film 6 has a thickness ranging, for example, from 5 nm to 100 nm. The WN film 9 has a thickness ranging, for example, from 2 nm to 40 nm. The W film 10 has a thickness ranging, for example, from 10 nm to 100 nm.

In the select gate transistor ST included in a flash memory according to the present embodiment, the WN film 9 is directly in contact with the p-type silicon layer 4 as the lower electrode layer 4 via the openings (EI portion) of the interpoly dielectric film 5 and the first polysilicon film 6. The WN film 9 is also in contact with the side face of the first polysilicon film 6 and the interpoly dielectric film 5 exposed by the EI portion.

The WN film 9 is preferably formed in such a way that the EI portion is not buried. This is intended to reduce the resistance of the gate electrode. For example, the dimension of the opening of the interpoly dielectric film 5 in a direction parallel to the surface of the semiconductor substrate can be increased to more than twice the thickness of the WN film 9.

FIG. 19B shows a cross section structure of a peripheral transistor along the gate length direction of the transistor in a flash memory according to the present embodiment.

FIG. 19B shows a peripheral transistor taking a MOS transistor as an example.

In a MOS transistor formation region 21, a gate electrode 3, GC of a MOS transistor as peripheral transistor Tr is provided above the p-type silicon region 1 via a gate insulating film 2.

As described above, the gate insulating film 2 of the peripheral transistor Tr is formed by using a film having the same material and the same thickness as those of the gate insulating film 2 of the memory cell transistor MT so that the number of manufacturing processes of flash memories can be reduced.

The gate electrode 3, GC of the peripheral transistor Tr includes a lower electrode layer 3 made of n-type semiconductor layer on the gate insulating film 2, the interpoly dielectric film 5 provided on the lower electrode layer 3 and having an opening (EI portion), and a gate contact layer GC provided on the interpoly dielectric film 5 and the lower electrode layer 3.

The lower electrode layer 3 of n-type semiconductor has a thickness ranging, for example, from 5 nm to 100 nm and is formed of polysilicon to which phosphorus, arsenic, or antimony in the concentration ranging, for example, 10¹⁸ cm⁻³ to 10²² cm⁻³ is added.

The gate contact layer GC is formed of the first p-type polysilicon film 6 provided on the interpoly dielectric film 5 and to which boron in the concentration ranging, for example, 10¹⁸ cm⁻³ to 10²² cm⁻³ is added, the WN film 9 provided on the lower electrode layer 3 and the polysilicon film 6, and the W film 10 stacked on the WN film 9. The first p-type polysilicon film 6 has a thickness ranging from 5 nm to 100 nm. The WN film 9 has a thickness ranging, for example, from 2 nm to 40 nm. The W film 10 has a thickness ranging, for example, from 10 nm to 100 nm. An opening is formed in the polysilicon film 6 in a position corresponding to the opening of the interpoly dielectric film 5.

In the peripheral transistor (for example, a MOS transistor) Tr included in a flash memory according to the present embodiment, the WN film 9 included in the gate contact layer GC is directly in contact with the n-type polysilicon layer 3 as a lower electrode layer via the opening formed in the polysilicon film 6 and the interpoly dielectric film 5.

Also regarding the peripheral transistor Tr, the WN film 9 is preferably formed in such a way that the EI portion is not buried. An interface resistance between the WN film 9 and the lower electrode layer 3 (n-type polysilicon film) may be lowered by additionally forming a WSi film 9Z in the range of, for example, 0.5 nm to 5 nm on the opposite side of the W film 10 with respect to the WN film 9. For example, the undersurface of the WSi film 9Z is in contact with the top surface of the lower electrode layer 3 (n-type polysilicon film) and the top surface of the WSi film 9Z is in contact with the WN film 9.

In a surface region of the p-type semiconductor region 1 as the MOS transistor formation region 21, an n-type diffusion layer 16 functioning as an LDD region of a source electrode and drain electrode of the MOS transistor is provided.

A P-type MOS transistor as the peripheral transistor Tr is different only in the conductivity type of the diffusion layer as a source/drain and has a gate electrode structure that is substantially the same as that of an N-type MOS transistor and is provided on a semiconductor substrate (for example, n-type well region).

Also when, like a flash memory according to the present embodiment, the memory cell transistor MT, the select gate transistor ST, and the peripheral transistor (for example, a MOS transistor) Tr have a structure shown in FIGS. 19A and 19B, effects similar to those of each embodiment described above can be obtained.

### <Manufacturing Method>

The manufacturing method of a flash memory according to the fifth embodiment will be described by using FIGS. 20A to 20C.

In FIGS. 20A to 20C, the manufacturing process of a memory cell transistor, select gate transistor, and peripheral transistor extracting a portion of a memory cell array region 20 and the peripheral region 21 is shown.

As shown in FIG. 20A, the n-type and p-type silicon layers 3, 4 are formed, by executing process that are substantially the same as the described above, on the gate insulating film 2 on the p-type silicon region 1 in the memory cell array region 20 and the peripheral region 21 respectively. The interpoly dielectric film 5 and the p-type first polysilicon film 6 are sequentially formed on the silicon layers 3, 4.

An opening (EI portion) is formed in the polysilicon film 6 and the interpoly dielectric film 5 in the select gate transistor formation region of the memory cell array region 20 and the peripheral region 21.

Then, the WN film 9 is deposited on the first polysilicon film 6. At this point, the WN film 9 is formed on the first polysilicon film 6 in the select gate transistor formation region and the peripheral region 21 and also on the polysilicon layers 3, 4 via the opening (EI portion). The WN film 9 is directly in contact with the p-type silicon layer 4 in the select gate transistor formation region and directly in contact with the n-type silicon layer 3 in the peripheral region 21.

The thickness of the WN film 9 and the dimension of the EI portion are preferably adjusted before the WN film 9 and the EI portion are formed so that the opening formed in the interpoly dielectric film 5 is not buried by the WN film 9. This can be achieved by, for example, increasing the dimension of the opening of the interpoly dielectric film 5 in a direction parallel to the surface of the semiconductor substrate to more than twice the thickness of the WN film 9.

The W film 10 is deposited on the WN film 9. Further, the cap material 11 and the mask material 12 are sequentially deposited on the W film 10.

By forming the WN film 9 on the first polysilicon film 6 included in the control gate electrode as described above, the formation process of a polysilicon film of the control gate electrode and one lithography process can be cut back. Also, the influence of contamination of polysilicon by organic matter that may be caused by the additional lithography process can be reduced. Thus, according to the present embodiment, the manufacturing process can be decreased and therefore, manufacturing costs can be reduced. In addition, depletion between silicon films included in a gate electrode can be inhibited.

Subsequently, as shown in FIGS. 20B and 20C, an opening is formed in a region between memory cell transistors by lithography and the mask material 12, the cap material 11, the W film 10, the WN film 9, the first polysilicon film 6, the interpoly dielectric film 5, and the polysilicon layer 4 are etched by the RIE method by executing processes that are substantially the same as the above processes. Accordingly, the control gate electrode CG and the floating gate electrode 4 of the memory cell transistor MT are formed.

The n-type diffusion layer 27 as a source/drain electrode of the memory cell transistor MT is formed by, for example, ion implantation or the like.

After a protective film 13 being formed, the insulating films 14, 15 are deposited on the mask material 12. Accordingly, the air gap AG is formed between the memory cell transistors MT.

Subsequently, gate electrodes of the select gate transistor ST and the peripheral transistor Tr are formed by gate processing of component members of the gate electrodes of the select gate transistor ST and the peripheral transistor (MOS transistor) Tr through lithography and etching in a region on the opposite side of the memory cell side of the select gate transistor formation region and the peripheral region 21.

Because the select gate layer SG of the select gate transistor ST and the gate contact layer GC of the peripheral transistor Tr are formed of the WN film 9 and the W film 10, there arises almost no difference in etching rate between the select gate transistor ST and the peripheral transistor Tr so that the select gate transistor ST and the peripheral transistor Tr can substantially simultaneously be processed by more uniform etching.

The sources/drains 27z, 16 of the transistors ST, Tr made of an n-type diffusion layer is formed by, for example, ion implantation, in the semiconductor region 1 in a region on the opposite side of the memory cell side of the select gate transistor formation region and a source/drain region of the peripheral transistor.

A p-type diffusion layer as a source/drain of a P-type MOS transistor as the peripheral transistor Tr is formed by an ion implantation into an n-type well using a gate electrode formed substantially simultaneously with an N-type MOS transistor as a mask in a process that is different from the formation process of an n-type diffusion layer.

Subsequently, an inter-layer insulating film, contact plug, and interconnects are sequentially formed as described above by using known technology to form a flash memory according to the present embodiment.

In a flash memory according to the present embodiment and the manufacturing process thereof, except that the lower electrode layer 3 of the peripheral transistor Tr (for example, a MOS transistor) formed in the peripheral region 21 is made of n-type (n⁺-type) polysilicon, the floating gate electrode 4 and the control gate electrode CG of the memory cell transistor MT, the lower electrode layer 4 and the select gate layer SG of the select gate transistor ST, and the gate contact layer GC of the peripheral transistor include the p-type polysilicon film 6. A laminated structure of the WN film 9 and the W film 10 is provided in the control gate electrode CG of the memory cell transistor MT, the select gate layer SG of the select gate transistor ST, and the gate contact layer GC of the peripheral transistor Tr.

In the present embodiment, the WN film 9 is directly in contact with the p-type and n-type polysilicon layers as lower electrode layers 4, 3 via the openings formed in the interpoly dielectric film 5 and the first polysilicon film 6 in the select gate transistor ST and the MOS transistor Tr.

Thus, a flash memory according to the present embodiment is different from the above embodiments in that the WN film 9 is directly in contact with the lower electrode layers 4, 3 in the gate electrode due to an EI structure in the select gate transistor ST and peripheral transistor Tr.

In the present embodiment, each of the gate electrode CG, GC can substantially simultaneously be formed by using substantially the same materials without using different component members of the control gate electrode CG and the gate contact layer GC for the memory cell transistor MT and the MOS transistor Tr.

According to a nonvolatile semiconductor memory in the fifth embodiment and the manufacturing method thereof, manufacturing costs of the nonvolatile semiconductor memory can be reduced. Also, according to a nonvolatile semiconductor memory in the present embodiment and the manufacturing method thereof, characteristics of the nonvolatile semiconductor memory can be improved.

### (6) Sixth Embodiment

A nonvolatile semiconductor memory (for example, a NAND flash memory) according to the sixth embodiment will be described with reference to FIGS. 21A to 22C. The description of the configurations and functions in the present embodiment that are substantially the same as those in the first to fifth embodiments will be described when necessary.

### <Structure>

The structure of a flash memory according to the present embodiment will be described by using FIGS. 21A and 21B.

FIG. 21A shows a cross section structure of a memory cell transistor and a select gate transistor along the gate length direction of the transistors in a NAND flash memory according to the present embodiment. In FIG. 21A, a structure in which three memory cell transistors are connected in series is shown.

In a memory cell array region 20, for example, the gate insulating film 2 of the memory cell transistor MT is provided on the p-type semiconductor region 1. As described above, the gate insulating film 2 is formed by using a single-layer film or a laminated film having a total thickness raging from 1 nm to 10 nm.

The floating gate electrode 4 made of a p-type semiconductor is provided on the gate insulating film 2.

The floating gate electrode 4 of the memory cell transistor MT is formed of p-type polysilicon to which boron is added in the concentration ranging from 10¹⁸ cm⁻³ to 10²² cm⁻³. The floating gate electrode 4 has a thickness ranging, for example, from 30 nm to 120 nm.

An interpoly dielectric film 5 is provided on the floating gate electrode 4. As described above, the interpoly dielectric film is formed by using a single-layer film or a laminated film having a total thickness raging from 2 nm to 30 nm.

A control gate electrode CG is provided on the interpoly dielectric film 5.

The control gate electrode CG includes a p-type (p⁺-type) first polysilicon film 6 which is provided on the interpoly dielectric film 6 and to which boron is added in the concentration ranging, from 10¹⁸ cm⁻³ to 10²² cm⁻³, and which is provided on the interpoly dielectric film 5, a W film 10A stacked on the polysilicon film 6, a WN film 9 stacked on the W film 10A, and a W film 10B stacked on the WN film 9. The first polysilicon film 6 has a thickness ranging, for example, from 5 nm to 100 nm. The W film 10A has a thickness ranging, for example, from 2 nm to 10 nm. The WN film 9 has a thickness ranging, for example, from 5 nm to 10 nm. The W film 10B has a thickness ranging, for example, from 10 nm to 100 nm.

In a gate electrode 4, CG of a memory cell transistor MT included in a flash memory according to the present embodiment, a control gate electrode CG includes only one layer of a p-type polysilicon layer 6 and a W layer 10A is directly stacked on the 1-layer polysilicon film (p-type silicon film) 6 included in the control gate electrode CG.

In the present embodiment, the memory cell transistor MT includes a laminated structure (W/WN/W laminated films) in which a WN film 9 is sandwiched between two W films 10A, 10B on a top portion of the control gate electrode CG and the W/WN/W laminated films become backing interconnects of the control gate electrode (word line).

A laminated film of polysilicon and WSi, CoSi, NiSi, or tungsten may be used for the control gate electrode CG. When a structure (for example, silicide) excluding a tungsten/polysilicon structure is used for the control gate electrode CG, the cap material 11 may not be provided on the control gate electrode CG.

N-type diffusion layers 27 to be a source/drain electrode of the memory cell transistor MT are formed in the semiconductor region 1 at both ends of the floating gate electrode 4 of memory cell transistors MT.

A memory cell of a floating gate type nonvolatile flash EEPROM is formed from the floating gate electrode 4, the control gate electrode CG, and an n-type diffusion layer 27 as a source/drain electrode.

NAND connection between the memory cell transistors MT is realized by the n-type diffusion layer 27 as a source/drain being shared by the adjacent memory cell transistors.

In the NAND-connected memory cell transistors MT, as described above, a select gate transistor ST is formed at one and the other end of the NAND-connected memory cell transistors to select a memory cell block.

The gate electrode of a select gate transistor ST is formed by using substantially the same material as that of the gate electrode of the memory cell transistor MT.

In the present embodiment, the p-type first polysilicon 6 and an interpoly dielectric film 5 are eliminated excluding a portion on the word line side (memory cell side) in a gate electrode 4, SG of the select gate transistor ST. The W film 10A is directly in contact with a lower electrode layer 4 made of the same material as that of the floating gate electrode 4 in a portion from which the first polysilicon film 6 and the interpoly dielectric film 5 are eliminated in the gate electrode 4, SG of the select gate transistor ST. Thus, the structure of the select gate transistor ST in the present embodiment is different from the structure of the select gate transistors in the above embodiments.

FIG. 21B shows a cross section structure in the channel length direction of a peripheral transistor. The peripheral transistor shown in FIG. 21B is a MOS transistor.

The MOS transistor as a peripheral transistor Tr is provided in a p-type silicon region 1.

A gate electrode 3, GC of the peripheral transistor Tr is formed above the p-type semiconductor region 1 via a gate insulating film 2.

The gate insulating film 2 is formed by using a film having the same material and the same thickness as those of the gate insulating film 2 of memory cell transistor MT so that the number of manufacturing processes of flash memories can be reduced.

The gate electrode 3, GC of the MOS transistor Tr as a peripheral transistor includes a lower electrode layer 3 of n-type semiconductor formed on the gate insulating film 2. The lower electrode layer 3 is made of an n-type polysilicon layer 3 having a thickness ranging from 5 nm to 100 nm. The polysilicon layer 3 as the lower electrode layer 3 has phosphorus, arsenic, or antimony in the concentration ranging from 10¹⁸ cm⁻³ to 10²² cm⁻⁸ added thereto.

In the MOS transistor as a peripheral transistor Tr included in a flash memory according to the present embodiment, a gate contact layer GC of the peripheral transistor Tr includes, for example, the W film 10A, the WN film 9 stacked on the W film 10A, and the W film 10B stacked on the WN film 9. The W film 10A has a thickness ranging, for example, 2 nm to 10 nm. The WN film 9 has a thickness ranging, for example, 5 nm to 10 nm. The W film 10B has a thickness ranging, for example, 10 nm to 100 nm.

In the present embodiment, the W film 10A in the lowest layer of the gate contact layer GC of the peripheral transistor (MOS transistor) Tr is stacked on the lower electrode layer 3 made of the n-type polysilicon layer 3.

In a peripheral region 21, an n-type diffusion layer 16 functioning as an LDD region of a source and drain of the MOS transistor is provided in a surface region of the p-type silicon region 1.

A P-type MOS transistor as a peripheral transistor is different only in the conductivity type of the diffusion layer as a source/drain and has a gate electrode structure that is substantially the same as that of an N-type MOS transistor and is provided on a semiconductor substrate (for example, on a n-type well region).

Like a flash memory according to the present embodiment, the memory cell transistor MT, the select gate transistor ST, and the peripheral transistor (for example, a MOS transistor) Tr have a structure shown in FIGS. 21A and 21B, effects similar to those of each embodiment described above can be obtained.

### <Manufacturing Method>

The manufacturing method of a flash memory according to the sixth embodiment will be described by using FIGS. 22A to 22C.

In FIGS. 22A to 22C, the manufacturing process of a memory cell transistor, select gate transistor, and peripheral transistor extracting a portion of a memory cell array region 20 and the peripheral region 21 is shown.

As shown in FIG. 22A, the n-type and p-type silicon layers 3, 4 are formed, like the manufacturing processes shown in FIGS. 17A to 17D described above, on the gate insulating film 2 in the p-type silicon region 1 in the memory cell array region 20 and the peripheral region 21 respectively. The interpoly dielectric film 5 and the p-type first polysilicon film 6 are sequentially formed on the silicon layers 3, 4.

Then, the interpoly dielectric film 5 and the p-type first polysilicon film 6 are selectively removed from in a select gate transistor formation region of the memory cell array region 20 and the peripheral region 21.

Subsequently, as shown in FIG. 22A, the W film 10A is formed on the p-type polysilicon film 6 and the p-type polysilicon layer 4 in the memory cell array region 20 and on the n-type polysilicon layer 3 in the peripheral region 21.

Then, the WN film 9 and the W film 10B are sequentially stacked on the W film 10A.

By forming the W films 10A, 10B and the WN film 9 on the first polysilicon film 6 included in the control gate electrode CG as described above, the formation process of a polysilicon film of the control gate electrode CG and one lithography process can be cut back. Also, the influence of contamination of polysilicon by organic matter that may be caused by the additional lithography process can be reduced. Therefore, according to the present embodiment, the manufacturing process of the flash memory can be decreased and manufacturing costs can be reduced.

Subsequently, as shown in FIGS. 22B and 22C, an opening is formed in a region between memory cell transistors by lithography and the mask material 12, the cap material 11, the W film 10B, the WN film 9, the W film 10A, the first polysilicon film 6, the interpoly dielectric film 5, and the polysilicon layer 4 are sequentially etched by the RIE method by executing processes that are substantially the same as the above processes. Accordingly, the control gate electrode CG and the floating gate electrode 4 of the memory cell transistor MT are formed.

An n-type diffusion layer 27 as a source/drain electrode of the memory cell transistor MT is formed in the semiconductor region 1 of the memory cell array region 20 as described above.

After the protective film 13 being formed, an air gap AG is formed between the memory cell transistors MT by the insulating films 14, 15 with poor coverage being deposited on the mask material 12.

Subsequently, gate electrodes of the select gate transistor ST and peripheral transistor Tr are formed by gate processing of component members of the gate electrodes of the select gate transistor Tr and the peripheral transistor Tr (MOS transistor) through lithography and etching in a region on the opposite side of the memory cell side of the select gate transistor formation region and the peripheral region 21.

Because the select gate layer SG of the select gate transistor ST and the gate contact layer GC of the peripheral transistor Tr are formed of the WN film 9 and the W film 10A, 10B, there arises almost no difference in etching rate between the select gate transistor ST and the peripheral transistor Tr so that the select gate transistor ST and the peripheral transistor Tr can substantially simultaneously be processed by more uniform etching.

The sources/drains 27z, 16 of the transistors ST, Tr made of an n-type diffusion layer is formed in the semiconductor region 1 in a region on the opposite side of the memory cell side of the select gate transistor formation region and a source/drain region of the peripheral transistor by, for example, ion implantation.

A p-type diffusion layer as a source/drain of a P-type MOS transistor as the peripheral transistor Tr is formed in an n-type well region using a gate electrode formed substantially simultaneously with an N-type MOS transistor as a mask in a process that is different from the formation process of an n-type diffusion layer.

Subsequently, an inter-layer insulating film, contact plug, and interconnects are sequentially formed as described above by using known technology to form a flash memory according to the present embodiment.

In a flash memory according to the present embodiment and the manufacturing process thereof, the control gate electrode CG of the memory cell transistor MT includes the p-type polysilicon film 6 on the interpoly dielectric film 5 and the W/WN/W laminated films 10A, 9, 10B on the p-type polysilicon film 6. Like the memory cell transistor MT, gate electrodes of the select gate transistor ST and the peripheral transistor Tr include the W/WN/W laminated films 10A, 9, 10B.

Siliciding of the lower portion of the W film 10A in contact with the p-type polysilicon film 6 may be caused so that the lower portion becomes a WSi film.

In the present embodiment, the interpoly dielectric film and first polysilicon film are removed from a portion in the gate electrode of the select gate transistor ST and in a portion neither interpoly dielectric film nor first polysilicon film is included, the W film 10A is stacked on the lower electrode layer 4 and directly in contact with the p-type silicon layer 4 as the lower electrode layer 4.

In the MOS transistor as the peripheral transistor Tr, neither interpoly dielectric film nor first polysilicon film is included in the gate electrode 3, GC and the W film 10A is stacked on the lower electrode layer 3 and directly in contact with the n-type silicon layer 3 as the lower electrode layer 3.

Thus, a flash memory according to the present embodiment is different from that in the above embodiments in that the lower electrode layers 4, 3 in the gate electrode and the W film 10A are directly in contact in the select gate transistor ST and peripheral transistor Tr.

According to the present embodiment, the interface resistance (contact resistance) between component members of the gate electrode of the select gate transistor ST and the peripheral transistor Tr can be reduced by the low-resistance W film 10A being in contact with the polysilicon layers as the lower electrode layers 3, 4.

The thickness of the W film 10A is preferably thinner than that of the W film 10B. If the W film 10A is thick, the first polysilicon 6 may disappear due to siliciding. On the other hand, the W film 10B stacked above the WN film 9 is not in contact with polysilicon and does not affect siliciding. Thus, the resistance of the gate electrode can be decreased by making the W film 10B thicker.

According to a nonvolatile semiconductor memory in the sixth embodiment and the manufacturing method thereof, as described above, manufacturing costs of the nonvolatile semiconductor memory can be reduced. Also, according to a nonvolatile semiconductor memory in the present embodiment and the manufacturing method thereof, characteristics of the nonvolatile semiconductor memory can be improved.

In the embodiments described above, instead of a laminated structure of the WN film and W film, a laminated structure (W/WN/W laminated film) in which the WN film 9 is sandwiched between the W films 10A, 10B described in the present embodiment may be applied to the control gate electrode CG of the memory cell transistor MT, the select gate layer SG of the select gate transistor ST, and the gate contact layer GC of the peripheral transistor Tr. The manufacturing method of a flash memory in this case is different only in that a process of depositing the W film 10A is added before the WN film 9 being deposited and otherwise, the manufacturing process is substantially the same.

### (7) Modification

A modification of a nonvolatile semiconductor memory according to the above embodiments will be described with reference to FIGS. 23A to 23C.

In the formation method of a floating gate electrode/lower electrode layer on a gate insulating film according to each of the above embodiments, an example in which the floating gate electrode made of p-type silicon of a memory cell transistor and the lower electrode layer made of n-type silicon of an N-type transistor are differently produced by using ion implantation has been described.

However, as will be described below, p-type and n-type silicon layers may be produced differently on the gate insulating films of a memory cell array region 20 and a peripheral region 21 by doping of impurity using a doping gas.

FIGS. 23A to 23C are sectional process charts showing the manufacturing process in the present modification when p-type and n-type silicon layers are produced differently on a gate insulating film by impurity doping using a doping gas.

As shown in FIG. 23A, an n-type silicon layer 3 is formed on a gate insulating film 2 in the memory cell array region 20 and the peripheral region 21 in such a way that phosphorus, arsenic, or antimony is added into the silicon layer 3 in the concentration ranging from 10¹⁸ cm⁻³ to 10²² cm⁻³ by doping using a doping gas.

Before the process shown in FIG. 23A, a process of forming an n-type well or p-type well in the semiconductor substrate can be executed by using ion implantation or the like.

As shown in FIG. 23B, a resist film 98 is formed on the n-type silicon layer 3 in a MOS transistor formation region in the peripheral region 21. In the memory cell array region 20, the resist film is opened and the top surface of the n-type silicon layer 3 in the memory cell array region 20 is exposed. The resist film 98 is used as a mask to etch the silicon layer 3 by the RIE method. Accordingly, the n-type silicon layer 3 in the memory cell array region 20 is removed.

After the n-type polysilicon film being removed from the memory cell array region 20, as shown in FIG. 23C, a p-type silicon layer 4 is formed on the gate insulating film 2 in such a way that boron is added into the polysilicon film 4 in the concentration ranging from 10¹⁸ cm⁻³ to 10²² cm⁻³ by impurity doping while silicon being deposited.

For example, the p-type silicon layer 4 is deposited on the n-type silicon layer 3 in the peripheral region 21.

Subsequently, a resist film is formed on the p-type silicon layer 4 in the memory cell array region 20 to selectively remove the p-type silicon layer 4 in the peripheral region 21.

Thus, the n-type and the p-type polysilicon films 3, 4 are formed on the gate insulating film 2 by doping using a doping gas respectively.

Subsequently, component members of each transistor such as an interpoly dielectric film 5 and control gate electrode CG are formed and processed on the n-type and the p-type polysilicon films 3, 4 produced differently by doping using a doping gas in the memory cell array region 20 and the peripheral region 21 by the manufacturing process described in the first to sixth embodiments to form a flash memory according to each of the above embodiments.

As described in the present modification, a p-type silicon layer as a floating gate electrode in a memory cell transistor and an n-type silicon layer of a gate electrode in a peripheral transistor may be produced differently by doping using a doping gas during deposition of the silicon layer.

Also when the present modification is used, effects described in the first to sixth embodiments are obtained.

### [Others]

Nonvolatile semiconductor memories according to the embodiments have been described by exemplifying NAND flash memories. However, the structure described in the above embodiments may be applied to a storage device of another circuit configuration such as a NOR flash memory if the storage device is a semiconductor storage device using a floating gate type memory cell transistor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory comprising:
a memory cell transistor to which data can electrically be written and from which data can electrically be erased, the memory cell transistor including a floating gate electrode having a first p-type silicon film, a control gate electrode having a second p-type silicon film, and a first inter-gate insulating film between the first and second p-type silicon films;
a first select gate transistor connected to one end of the memory cell transistor; and
a first field effect transistor including a gate insulating film and a gate electrode, the gate electrode having a lower electrode layer above the gate insulating film, an upper electrode layer above the lower electrode layer, and a second inter-gate insulating film between the lower electrode layer and the upper electrode layer, the lower electrode layer having a first n-type silicon film, the second inter-gate insulating film having a first opening, and the upper electrode layer having a third p-type silicon film, wherein the third p-type silicon film is provided on the first n-type silicon film via the first opening.

2. The nonvolatile semiconductor memory according to claim 1, wherein
the gate electrode includes a pn junction formed of the first n-type silicon film and the third p-type silicon film.

3. The nonvolatile semiconductor memory according to claim 1, wherein
the third p-type silicon film has an impurity concentration that is substantially same as that of the second p-type silicon film.

4. The nonvolatile semiconductor memory according to claim 1, wherein
the second and third p-type silicon films have an impurity concentration set to a range of 10¹⁸ cm⁻³ to 10²² cm⁻³ and the first n-type silicon film has an impurity concentration set to the range of 10¹⁸ cm⁻³ to 10²² cm⁻³.

5. The nonvolatile semiconductor memory according to claim 1, wherein
the control gate electrode and the upper electrode layer further include a laminated film including a tungsten nitride film and a first tungsten film, respectively,
the tungsten nitride film is provided above the second p-type silicon film and the first tungsten film is provided above the tungsten nitride film in the control gate electrode, and
the tungsten nitride film is provided above the third p-type silicon film and the first tungsten film is provided above the tungsten nitride film in the upper electrode layer.

6. The nonvolatile semiconductor memory according to claim 5, wherein
the laminated film further includes a tungsten silicide film,
the tungsten silicide film is in contact with the second p-type silicon film in the control gate electrode, and
the tungsten silicide film is in contact with the third p-type silicon film in the upper electrode layer.

7. The nonvolatile semiconductor memory according to claim 1, wherein
the first select gate transistor includes a lower select gate layer having a fourth p-type silicon film and an upper select gate layer having a fifth p-type silicon film and provided above the lower select gate layer,
the fifth p-type silicon film is connected to the fourth p-type silicon film,
the fourth p-type silicon film has an impurity concentration that is substantially same as that of the first p-type silicon film, and
the fifth p-type silicon film has an impurity concentration that is substantially same as that of the second p-type silicon film.

8. A nonvolatile semiconductor memory comprising:
a memory cell transistor to which data can electrically be written and from which data can electrically be erased, the memory cell transistor including a floating gate electrode having a first p-type silicon film, a control gate electrode having a second p-type silicon film, and a first inter-gate insulating film between the first and second p-type silicon films;
a first select gate transistor connected to one end of the memory cell transistor; and
a first field effect transistor including a gate insulating film and a gate electrode, the gate electrode having a lower electrode layer above the gate insulating film and an upper electrode layer on the lower electrode layer, the lower electrode layer having a first n-type silicon film, and the upper electrode layer having a third p-type silicon film, wherein the third p-type silicon film is provided on the first n-type silicon film.

9. The nonvolatile semiconductor memory according to claim 8, wherein
the gate electrode includes a pn junction formed of the first n-type silicon film and the third p-type silicon film.

10. The nonvolatile semiconductor memory according to claim 8, wherein
the third p-type silicon film has an impurity concentration that is substantially same as that of the second p-type silicon film.

11. The nonvolatile semiconductor memory according to claim 8, wherein
the second and third p-type silicon films have an impurity concentration set to a range of 10¹⁸ cm⁻³ to 10²² cm⁻³ and the first n-type silicon film has an impurity concentration set to the range of 10¹⁸ cm⁻³ to 10²² cm⁻³.

12. The nonvolatile semiconductor memory according to claim 8, wherein
the control gate electrode and the upper electrode layer further include a laminated film including a tungsten nitride film and a first tungsten film, respectively,
the tungsten nitride film is provided above the second p-type silicon film and the first tungsten film is provided above the tungsten nitride film in the control gate electrode, and
the tungsten nitride film is provided above the third p-type silicon film and the first tungsten film is provided above the tungsten nitride film in the upper electrode layer.

13. The nonvolatile semiconductor memory according to claim 12, wherein
the laminated film further includes a tungsten silicide film,
the tungsten silicide film is in contact with the second p-type silicon film in the control gate electrode, and
the tungsten silicide film is in contact with the third p-type silicon film in the upper electrode layer.

14. The nonvolatile semiconductor memory according to claim 8, wherein
the first select gate transistor includes a lower select gate layer having a fourth p-type silicon film and an upper select gate layer having a fifth p-type silicon film and provided above the lower select gate layer,
the fifth p-type silicon film is connected to the fourth p-type silicon film,
the fourth p-type silicon film has an impurity concentration that is substantially same as that of the first p-type silicon film, and
the fifth p-type silicon film has an impurity concentration that is substantially same as that of the second p-type silicon film.

15. A nonvolatile semiconductor memory comprising:
a memory cell transistor to which data can electrically be written and from which data can electrically be erased, the memory cell transistor including a floating gate electrode having a first p-type silicon film, a control gate electrode having a second p-type silicon film, and a first inter-gate insulating film between the first and second p-type silicon films;
a first select gate transistor connected to one end of the memory cell transistor; and
a first field effect transistor including a gate insulating film and a gate electrode, the gate electrode having a lower electrode layer above the gate insulating film and an upper electrode layer on the lower electrode layer, the lower electrode layer having a first n-type silicon film, the upper electrode layer having a first laminated film, and the first laminated film including a first tungsten nitride film and a first tungsten film, wherein the first laminated film is provided on the lower electrode layer.

16. The nonvolatile semiconductor memory according to claim 15, wherein
the first laminated film further includes a tungsten silicide film and the tungsten silicide film is in contact with the lower electrode layer.

17. The nonvolatile semiconductor memory according to claim 15, wherein
the first field effect transistor includes a second inter-gate insulating film between the lower electrode layer and the upper electrode layer, and
the first tungsten nitride film is in contact with the first n-type silicon film via an opening provided in the second inter-gate insulating film.

18. The nonvolatile semiconductor memory according to claim 15, wherein
the first laminated film further includes a second tungsten film,
the first tungsten film is stacked above the first n-type silicon film,
the first tungsten nitride film is stacked above the first tungsten film, and
the second tungsten film is stacked above the first tungsten nitride film.

19. The nonvolatile semiconductor memory according to claim 15, wherein
the control gate electrode further includes a second laminated film above a second p-type silicon film, and
the second laminated film includes a second tungsten nitride film and a third tungsten film on the second tungsten nitride film.

20. The nonvolatile semiconductor memory according to claim 15, wherein
the first select gate transistor includes a lower select gate layer having a third p-type silicon film, an upper select gate layer having a fourth p-type silicon film and a third laminated film, and a third inter-gate insulating film having an opening and provided between the lower and upper select gate layers,
the third laminated film includes a third tungsten nitride film and a fourth tungsten film on the third tungsten nitride film,
the third tungsten nitride film is connected to the third p-type silicon film via the opening,
the third p-type silicon film has an impurity concentration that is substantially same as that of the first p-type silicon film, and
the fourth p-type silicon film has an impurity concentration that is substantially same as that of the second p-type silicon film.
